(19) United States
(12) Patent Application Publication
(10) Pub. No.: US 2024/0014265 A1
(43) Pub. Date: Jan. 11, 2024

(54) Gate Isolation Wall for Semiconductor Device

(71) Applicant: Taiwan Semiconductor Manufacturing Co., Ltd., Hsinchu (TW)

(72) Inventors: Lung-Kun CHU, New Taipei City (TW); Jia-Ni YU, New Taipei City (TW); Chun-Fu LU, Hsinchu (TW); Chung-Wei HSU, Hsinchu County (TW); Mao-Lin HUANG, Hsinchu City (TW); Kuo-Cheng CHIANG, Zhubei City (TW); Chih-Hao WANG, Baoshan Township (TW)

(73) Assignee: Taiwan Semiconductor Manufacturing Co., Ltd., Hsinchu (TW)

(21) Appl. No.: 18/188,306

(22) Filed: Mar. 22, 2023

Related U.S. Application Data
(60) Provisional application No. 63/383,183, filed on Nov. 10, 2022.
(60) Provisional application No. 63/367,856, filed on Jul. 7, 2022.

(51) Int. Cl. H01L 29/06; H01L 29/786; H01L 29/775; H01L 29/66; H01L 29/423; H01L 27/092; H01L 21/8238

(52) U.S. Cl. CPC H01L 29/0673; H01L 29/78696; H01L 29/775; H01L 29/66439; H01L 29/42392; H01L 27/092; H01L 21/823807; H01L 21/823878

(57) ABSTRACT

The present disclosure describes a semiconductor device having an isolation structure. The semiconductor structure includes a set of nanostructures on a substrate, a gate dielectric layer wrapped around the set of nanostructures, a work function metal layer on the gate dielectric layer and around the set of nanostructures, and the isolation structure adjacent to the set of nanostructures and in contact with the work function metal layer. A portion of the work function metal layer is on a top surface of the isolation structure.

### CROSS-REFERENCE TO RELATED APPLICATIONS

This application claims the benefit of U.S. Provisional Patent Application No. 63/383,183, titled “Gate Isolation Wall for Semiconductor Device,” filed Nov. 10, 2022, and U.S. Provisional Patent Application No. 63/367,856, titled “Semiconductor Device with Gate Isolation Wall and Method for Forming the Same,” filed Jul. 7, 2022, the disclosures of which are incorporated by reference in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of defects control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a gate isolation wall, in accordance with some embodiments.

FIGS. 2A-2B, 3A-3D, and 4 illustrates plane views and cross-sectional views of a semiconductor device having a gate isolation wall, in accordance with some embodiments.

FIG. 5 is a flow diagram of a method for fabricating a semiconductor device having a gate isolation wall, in accordance with some embodiments.

FIGS. 6-31 illustrate plane views and cross-sectional views of a semiconductor device having a gate isolation wall, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With advances in semiconductor technology, multi-gate devices have been introduced to improve gate control by increasing gate-channel coupling, reducing off-state current, and reducing short-channel effects (SCEs). One such multi-gate device is the nanostructure transistor, which includes the gate-all-around field effect transistor (GAA FET), the nanosheet transistor, the nanowire transistor, the multi bridge channel transistor, the nano-ribbon transistor, and other similar structured transistors. The nanostructure transistor provides a channel in a stacked nanosheet/nanowire configuration. The GAA FET device derives its name from the gate structure that can extend around the channel and provide gate control of the channel on multiple sides of the channel. Nanostructure transistor devices are compatible with MOSFET manufacturing processes and their structure allows them to be scaled while maintaining gate control and mitigating SCEs.

Gate structures in nanostructure transistors can extend over two or more of the nanostructure transistors. For example, the gate structures can extend across multiple active regions (e.g., fin regions) of the nanostructure transistors. Once the gate structures are formed, a patterning process can “cut” one or more of the gate structures into shorter sections according to the desired structure. In other words, the patterning process can remove gate portions of the one or more gate structures to form one or more isolation trenches (also referred to as “metal cuts”) between the nanostructure transistors and separate the gate structures into shorter sections. This process is referred to as a cut-metal-gate (CMG) process. Subsequently, the isolation trenches formed between the separated sections of the gate structures can be filled with a dielectric material, such as silicon nitride (SiN) to form gate isolation structures, which can electrically isolate the separated gate structure sections.

With increasing demand for lower power consumption, higher performance, and smaller area (collectively referred to as “PPA”) of semiconductor devices, nanostructure transistor devices can have their challenges. For example, during the CMG process, metal gate structures on the side of the stacked nanosheet/nanowire channels can be removed (referred to as “end cap reduction”) to improve device performance. The end cap reduction can increase threshold voltage (Vt) variations across nanostructure transistors. Additionally, for the stacked nanosheet/nanowire channels having a forksheet architecture (also referred to as pi-gate), sidewall spacers can be damaged during the nanosheet/nanowire channel formation process. The sidewall spacer damage can cause metal gate extrusion and source/drain (S/D) epitaxial defects, which can degrade device performance and manufacturing yield. Furthermore, in the forksheet/pi-gate architecture, the isolation wall structures between the stacked nanosheet/nanowire channels can have seams or voids during formation. Subsequently-formed metal gate structures can fill the seams or voids and can be electronically shorted to adjacent S/D contact structures through the seams or voids.

Various embodiments in the present disclosure provide example methods for forming a gate isolation wall in a semiconductor device having nanostructure transistors (e.g., a GAA FETs) and/or other semiconductor devices in an integrated circuit (IC). The semiconductor device can have first and second sets of nanostructure channels and a gate dielectric layer wrapped around the first and second sets of nanostructure channels. The semiconductor device can further include a first work function metal layer around the first set of nanostructure channels and a second work function metal layer around the second set of nanostructure channels. A gate isolation wall can be disposed between the first and second sets of nanostructure channels and in contact with the first and second work function metal layers. A gate isolation structure can be disposed on the gate isolation wall to electrically isolate the gate structures on the first and second sets of nanostructure channels. In some embodiments, the semiconductor device can include a dielectric liner between the nanostructure channels and the gate isolation wall. In some embodiments, the semiconductor device can include an air gap between the nanostructure channels and the gate isolation wall. With the gate isolation wall and the dielectric liner, the Vt uniformity across the nanostructure transistors can be improved, the metal gate extrusion defects and S/D epitaxial defects can be reduced, and the electrical short defects between the metal gate structures and the S/D contact structures can be reduced.

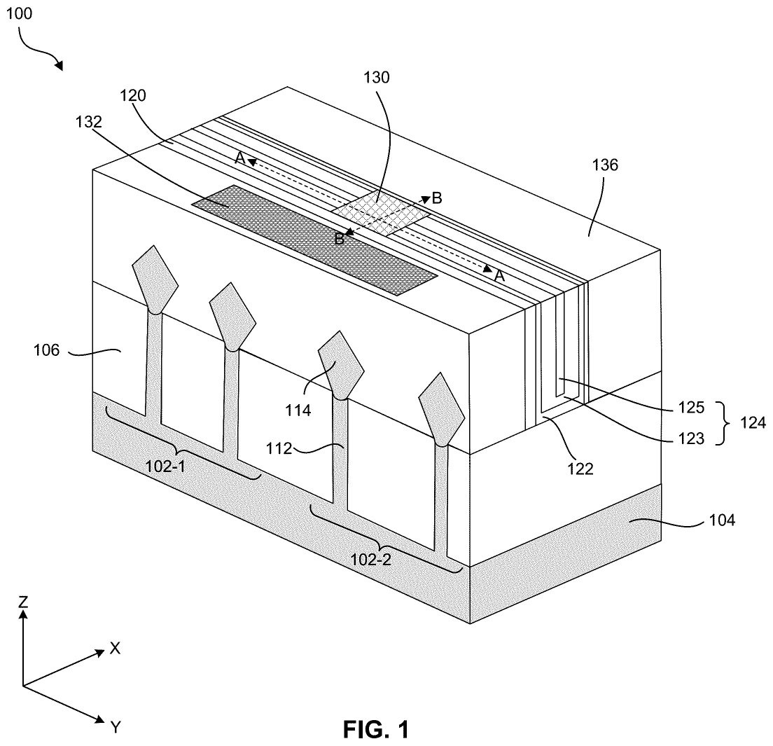

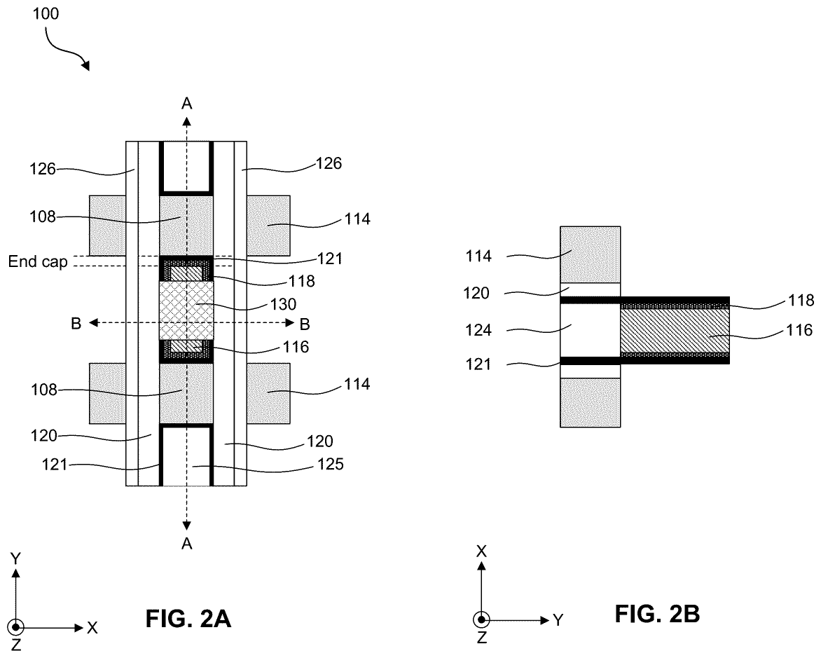

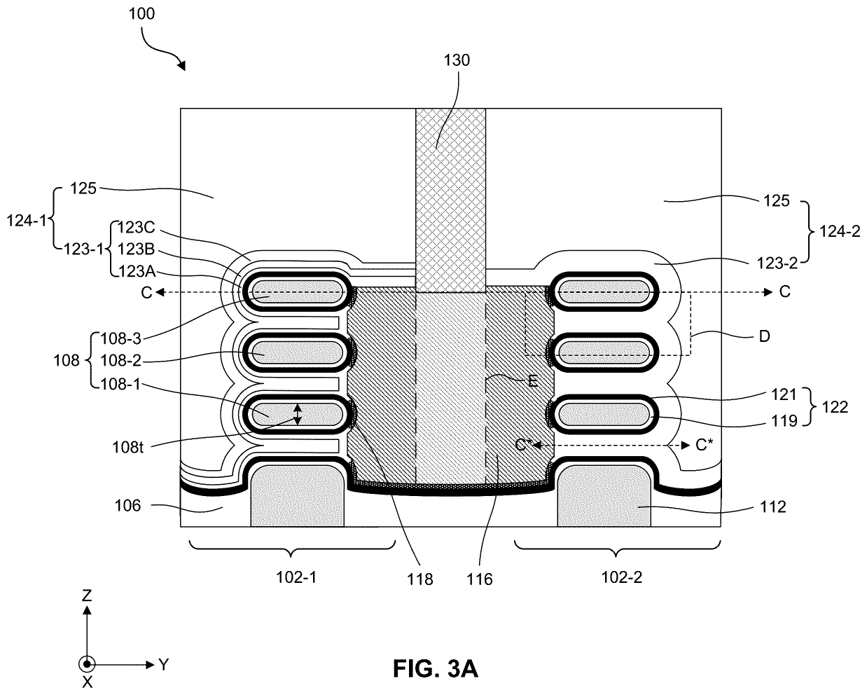

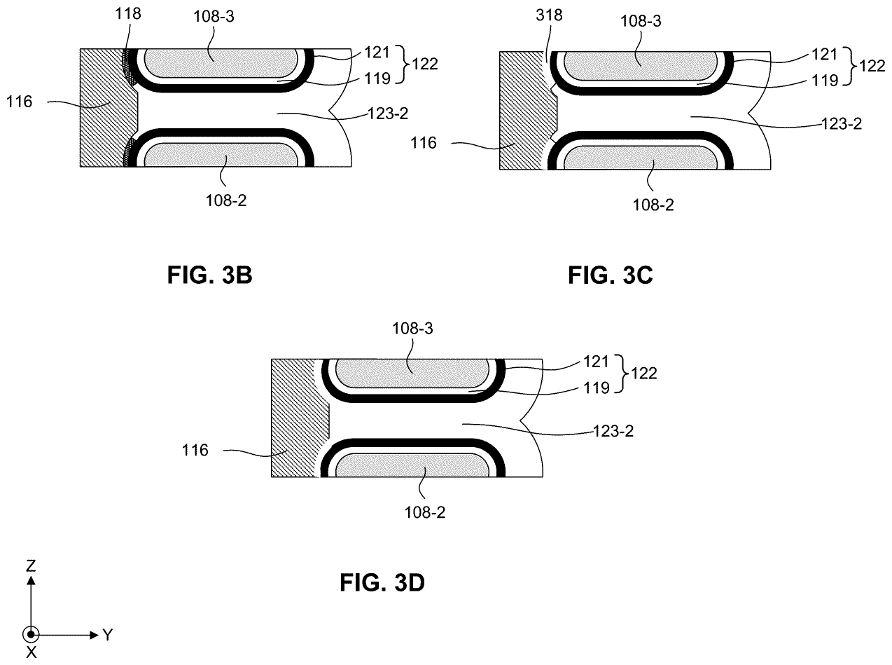

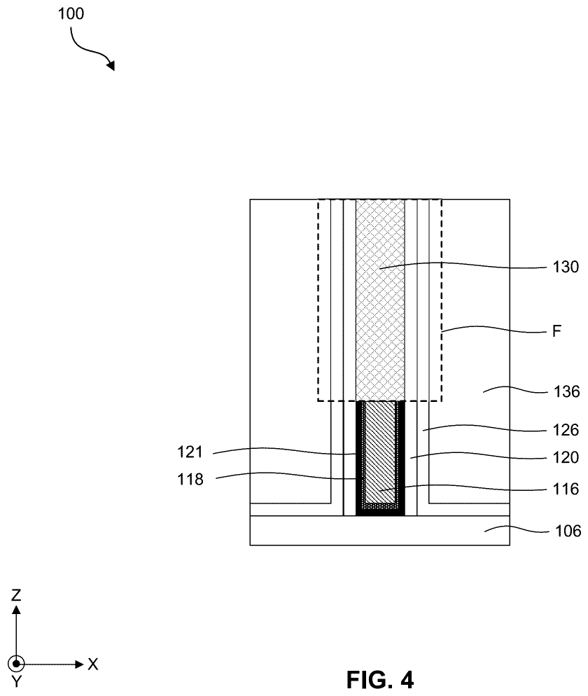

FIG. 1 illustrates an isometric view of a semiconductor device 100 having a gate isolation wall, in accordance with some embodiments. FIGS. 2A-2B illustrate partial plane views of semiconductor device 100 across planes C-C and C*-C* shown in FIG. 3A, in accordance with some embodiments. FIG. 3A illustrates a partial cross-sectional view of semiconductor device 100 along line A-A shown in FIGS. 1 and 2A, in accordance with some embodiments. FIGS. 3B-3D illustrate enlarged region D of semiconductor device 100 shown in FIG. 3A, in accordance with some embodiments. FIG. 4 illustrates a partial cross-sectional view of semiconductor device 100 along line B-B shown in FIGS. 1 and 2A, in accordance with some embodiments.

In some embodiments, semiconductor device 100 can include nanostructure transistors 102-1 and 102-2, as shown in FIGS. 1 and 3A. Referring to FIGS. 1-4, semiconductor device 100 having nanostructure transistors 102-1 and 102-2 can be formed on a substrate 104 and can be isolated by shallow trench isolation (STI) regions 106, gate isolation wall 116, and gate isolation structure 130. Each of nanostructure transistors 102-1 and 102-2 can include nanostructures 108-1, 108-2, and 108-3 (collectively referred to as “nanostructures 108”), fin structures 112, gate dielectric layer 122, gate structures 124-1 and 124-2 (collectively referred to as “gate structures 124”), gate spacers 120, S/D structures 114, dielectric liner 118, etch stop layer (ESL) 126, S/D contact structures 132, and interlayer dielectric (ILD) layer 136.

In some embodiments, nanostructure transistors 102-1 and 102-2 can be both n-type nanostructure field-effect transistors (NFETs). In some embodiments, nanostructure transistor 102-1 can be an NFET and have n-type S/D structures 114. Nanostructure transistor 102-2 can be a p-type nanostructure field-effect transistor (PFET) and have p-type S/D structures 114. In some embodiments, nanostructure transistors 102-1 and 102-2 can be both PFETs. Though FIG. 1 shows two nanostructure transistors, semiconductor device 100 can have any number of nanostructure transistors. In addition, semiconductor device 100 can be incorporated into an IC through the use of other structural components, such as conductive vias, conductive lines, dielectric layers, passivation layers, and interconnects, which are not shown for simplicity. The discussion of elements of nanostructure transistors 102-1 and 102-2 with the same annotations applies to each other, unless mentioned otherwise. And like reference numerals generally indicate identical, functionally similar, and/or structurally similar elements.

Referring to FIG. 1, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between nanostructure transistors 102-1 and 102-2 from each other and from neighboring nanostructure transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-4, nanostructures 108 and fin structures 112 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1 and 2A, nanostructures 108 and fin structures 112 can extend along an X-axis and through nanostructure transistors 102-1 and 102-2. In some embodiments, nanostructures 108 and fin structures 112 can be disposed on substrate 104. Nanostructures 108 can include a set of nanostructures 108-1, 108-2, and 108-3, which can be in the form of nanosheets, nanowires, or nano-ribbons. Each of nanostructures 108 can form a channel region underlying gate structures 124 of nanostructure transistors 102-1 and 102-2. In some embodiments, nanostructures 108 and fin structures 112 can include semiconductor materials similar to or different from substrate 104. In some embodiments, nanostructures 108 and fin structures 112 can include silicon. In some embodiments, nanostructures 108 can include silicon germanium. The semiconductor materials of nanostructures 108 can be undoped or can be in-situ doped during their epitaxial growth process. In some embodiments, each of nanostructures 108 can have a thickness 108t along a Z-axis ranging from about 5 nm to about 15 nm. A distance between each of nanostructures 108 along a Z-axis can range from about 9 nm to about 12 nm. As shown in FIGS. 1-4, nanostructures 108 under gate structures 124 can form channel regions of semiconductor device 100 and represent current carrying structures of semiconductor device 100. In some embodiments, a channel length (Lg) for nanostructures 108 under gate structures 124 can range from about 10 nm to about 18 nm. Though three layers of nanostructures 108 are shown in FIG. 3A, nanostructure transistors 102-1 and 102-2 can have any number of nanostructures 108.

Referring to FIGS. 1-4, gate dielectric layer 122 and gate structures 124 can be multi-layered structures and can wrap around middle portions of nanostructures 108. In some embodiments, each of nanostructures 108 can be wrapped around by one or more layers of gate structures 124, in which gate structures 124 can be referred to as “gate-all-around (GAA) structures” and nanostructure transistors 102-1 and 102-2 can also be referred to as “GAA FETs 102-1 and 102-2.”

As shown in FIG. 3A, gate dielectric layer 122 can include an interfacial layer 119 and a high-k dielectric layer 121. In some embodiments, gate dielectric layer 122 can include high-k dielectric layer 121 in direct contact with nanostructures 108. The term “high-k” can refer to a high dielectric constant. In the field of semiconductor device structures and manufacturing processes, high-k can refer to a dielectric constant that is greater than the dielectric constant of silicon oxide (e.g., greater than about 3.9). In some embodiments, interfacial layer 119 can include silicon oxide formed by a deposition process or an oxidation process. In some embodiments, high-k dielectric layer 121 can include hafnium oxide, zirconium oxide, and other suitable high-k dielectric materials. As shown in FIGS. 3A-3C, gate dielectric layer 122 can wrap around each of nanostructures 108, and thus electrically isolate nanostructures 108 from each other and from conductive gate structures 124 to prevent shorting between gate structures 124 and nanostructures 108 during operation of nanostructure transistors 102-1 and 102-2. In some embodiments, interfacial layer 119 can have a thickness ranging from about 1 nm to about 1.5 nm. In some embodiments, high-k dielectric layer 121 can have a thickness ranging from about 1 nm to about 2.5 nm. In some embodiments, as shown in FIGS. 2A-2B, high-k dielectric layer 121 can be disposed on gate spacers 120. In some embodiments, as shown in FIGS. 3A-3D, nanostructures 108 can have a forksheet/pi-gate architecture. As shown in FIG. 2B, high-k dielectric layer 121 can be disposed between gate spacers 120 and conductive gate structures 124 to protect gate spacers 120 during the sheet formation of nanostructures 108. As a result, the metal gate extrusion and S/D epitaxial defects can be reduced, and thus the device performance and manufacturing yield can be improved.

In some embodiments, as shown in FIG. 3A, gate structure 124-1 can include work function metal layers 123A, 123B, and 123C (collectively refer to as “work function metal layer 123-1”) and a metal fill 125. Gate structure 124-2 can include work function metal layer 123-2 and metal fill 125. Work function metal layers 123-1 and 123-2 (collectively refer to as “work function metal layers 123”) can wrap around nanostructures 108 and can include work function metals to tune the Vt of nanostructure transistors 102-1 and 102-2. In some embodiments, as shown in FIGS. 3A-3D, work function metal layer 123A can surround four sides of nanostructures 108 and work function metal layer 123B can surround three sides of nanostructures 108. In some embodiments, as shown in FIG. 3A, a portion of work function metal layers 123-1 and 123-2 can be disposed on a top surface of gate isolation wall 116. Though FIGS. 3A-3C illustrate three work function metal layers in nanostructure transistor 102-1 and one work function metal layer in nanostructure transistor 102-2, nanostructure transistors 102-1 and 102-2 can include any number of work function metal layers for Vt tuning (e.g., ultra-low Vt, low Vt, and standard Vt.)

In some embodiments, the top surface of gate isolation wall 116 can be disposed between top and bottom surfaces of top nanostructures 108-3. Accordingly, a height of gate isolation wall 116 can be less than a height of nanostructures 108. In some embodiments, the height of gate isolation wall 116 can control a coverage of work function metal layers 123 wrapping around top nanostructures 108-3.

In some embodiments, n-type work function metal layers 123 (e.g., work function metal layer 123-1) can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, p-type work function metal layers 123 (e.g., work function metal layer 123-2) can include titanium nitride, titanium silicon nitride, tantalum nitride, tungsten carbon nitride, tungsten, molybdenum, or other suitable work function metals. In some embodiments, work function metal layers 123 can include a single metal layer (e.g., work function metal layer 123-2) or a stack of metal layers (e.g., work function metal layer 123-1). The stack of metal layers can include work function metals having work-function values equal to or different from each other. In some embodiments, work function metal layers 123 can have a thickness ranging from about 2 nm to about 6 nm.

Metal fill 125 can include titanium, tantalum, aluminum, cobalt, tungsten, nickel, ruthenium, or other suitable conductive materials. Depending on the spaces between adjacent nanostructures 108 and the thicknesses of the layers of gate structures 124, nanostructures 108 can be wrapped around by one or more layers of gate structures 124 filling the spaces between adjacent nanostructures 108.

Referring to FIGS. 1-4, gate spacers 120 can be disposed on sidewalls of gate structures 124 and in contact with gate dielectric layer 122. Gate spacers 120 can include insulating materials, such as silicon oxide, silicon nitride, silicon oxynitride, silicon carbonitride, silicon oxycarbide, silicon oxycarbonitride, a low-k material, and a combination thereof. Gate spacers 120 can include a single layer or a stack of insulating layers. In some embodiments, gate spacers 120 can have a low-k material with a dielectric constant less than about 3.9 (e.g., about 3.5, about 3.0, or about 2.8).

S/D structures 114 can be disposed on substrate 104 and on opposing sides of nanostructures 108. S/D structures 114 can function as S/D regions of nanostructure transistors 102-1 or 102-2. In some embodiments, S/D structures 114 can have any geometric shape, such as a polygon, an ellipsis, and a circle. In some embodiments, S/D structures 114 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 124. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 114 can include silicon and can be in-situ doped during an epitaxial growth process using n-type dopants, such as phosphorus and arsenic. In some embodiments, S/D structures 114 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 114 can include one or more epitaxial layers, where each epitaxial layer can have different compositions.

In some embodiments, S/D contact structures 132 can be disposed on S/D structures 114. S/D contact structures 132 can be configured to connect S/D structures 114 to other elements of semiconductor device 100 and/or of the integrated circuit. S/D contact structures 132 can be formed within ILD layer 136. According to some embodiments, S/D contact structures 132 can include metal silicide layers and conductive regions disposed on metal silicide layers (not shown). In some embodiments, the metal silicide layers can include metal silicides formed from one or more low work function metals deposited on epitaxial fin regions 114. Examples of work function metal(s) used for forming the metal silicide layers can include titanium, tantalum, nickel and/or other suitable work function metals. In some embodiments, the conductive regions can include one or more metals, such as ruthenium, cobalt, nickel, and other suitable metals.

Referring to FIGS. 1-4, in some embodiments, ESL 126 can be disposed on STI regions 106, S/D structures 114, and sidewalls of gate spacers 120. ESL 126 is not shown in FIG. 1 for simplicity. ESL 126 can be configured to protect STI regions 106, S/D structures 114, and gate structures 124 during the formation of S/D contact structures on S/D structures 114. In some embodiments, ESL 126 can include, for example, silicon oxide, silicon nitride, silicon oxynitride, silicon carbide, silicon carbonitride, boron nitride, silicon boron nitride, silicon carbon boron nitride, or a combination thereof.

ILD layer 136 can be disposed on ESL 126 over S/D structures 114 and STI regions 106. ILD layer 136 can include a dielectric material deposited using a deposition method suitable for flowable dielectric materials. For example, flowable silicon oxide can be deposited using flowable chemical vapor deposition (FCVD). In some embodiments, the dielectric material can include silicon oxide. In some embodiments, ILD layer 136 is not shown in FIG. 4 for simplicity.

Referring to FIGS. 1-4, gate isolation wall 116 can be disposed between nanostructures 108 of nanostructure transistor 102-1 and nanostructures 108 of nanostructure transistor 102-2. In some embodiments, as shown in FIG. 3A, gate isolation wall 116 can be disposed on dielectric liner 118 above STI regions 106. In some embodiments, as shown in FIGS. 2A and 4, gate isolation wall 116 can be confined between gate spacers 120 and enclosed by dielectric liner 118 and high-k dielectric layer 121. As a result, gate structures 124 may not be shorted to S/D contact structures 132 through voids/seams in gate isolation wall 116. In some embodiments, gate isolation wall 116 can include a dielectric material, such as silicon oxide, aluminum oxide, zirconium oxide, silicon nitride, and silicon carbon oxynitride. In some embodiments, as shown in FIG. 3A, sidewalls of gate isolation wall 116 adjacent to nanostructures 108 can have concave and convex surfaces arranged in an alternate configuration. With gate isolation wall 116, work function metal layers 123 can be uniformly formed in nanostructure transistors 102-1 and 102-2 and other nanostructure transistors. As a result, the Vt uniformity across nanostructure transistors in semiconductor device 100 can be improved.

Referring to FIGS. 2A, 2B, 3A, 3B, and 4, dielectric liner 118 can be disposed on high-k dielectric layer 121 at the bottom of gate isolation wall 116 and between high-k dielectric layer 121 and gate isolation wall 116 adjacent to the side surfaces of nanostructures 108. In some embodiments, as shown in FIGS. 2A-2B and 3A-3C, dielectric liner 118 can act as an end cap dielectric of nanostructure transistors 102 to cap the end portion of gate structures 124. The dimensions of dielectric liner 118 can control the uniformity of work function metal layers 123 on nanostructures 108. In some embodiments, dielectric liner 118 can have a thickness ranging from about 1 nm to about 3 nm. In some embodiments, dielectric liner 118 can include silicon oxide, aluminum oxide, zirconium oxide, silicon nitride, silicon carbon oxynitride, or other suitable dielectric materials.

In some embodiments, dielectric liner 118 can have a high etch selectivity with respect to high-k dielectric layer 121 and gate isolation wall 116. The term “etch selectivity” can refer to the ratio of the etch rates of two different materials under the same etching conditions. In some embodiments, the etch selectivity between dielectric liner 118 and high-k dielectric layer 121 can be greater than about 100 to control the end cap dimensions and the uniformity of work function metal layers 123 on nanostructures 108. In some embodiments, the etch selectivity between dielectric liner 118 and gate isolation wall 116 can be greater than about 100 to control the end cap dimensions and the uniformity of work function metal layers 123 on nanostructures 108.

In some embodiments, as shown in FIG. 3C, dielectric liner 118 can be replaced by an air gap 318 between high-k dielectric layer 121 and gate isolation wall 116. In some embodiments, air gap 318 can reduce the parasitic capacitance of nanostructure transistors 102 and improve device performance. In some embodiments, as shown in FIG. 3D, air gap 318 can be filled with work function metal layers 123 and work function metal layers 123 can wrap around nanostructures 108, which can improve the gate control of nanostructure transistors 102 and mitigate SCEs.

Referring to FIGS. 1-4, gate isolation structure 130 can be disposed on the top surface of gate isolation wall 116. In some embodiments, as shown in FIG. 3A, gate isolation structure 130 can extend through metal fill 125 and can electrically isolate metal fill 125 between nanostructure transistors 102-1 and 102-2. In some embodiments, gate isolation structure 130 can include silicon nitride, silicon oxide, and/or other suitable dielectric materials. In some embodiments, gate isolation structure 130 can include a single dielectric layer or a stack of dielectric layers. In some embodiments, gate isolation structure 130 can extend vertically through metal fill 125 and gate isolation wall 116, as shown by dashed region E in FIG. 3A. In some embodiments, gate isolation structure 130 can extend through dielectric liner 118 and high-k dielectric layer 121 into STI regions 106 (not shown). In some embodiments, as shown in FIG. 2, gate isolation structure 130 can be confined between gate spacers 120. In some embodiments, as shown by dashed region F in FIG. 4, gate isolation structure 130 can extend horizontally along an X-axis across gate spacers 120 and ESL 126 into ILD layer 136.

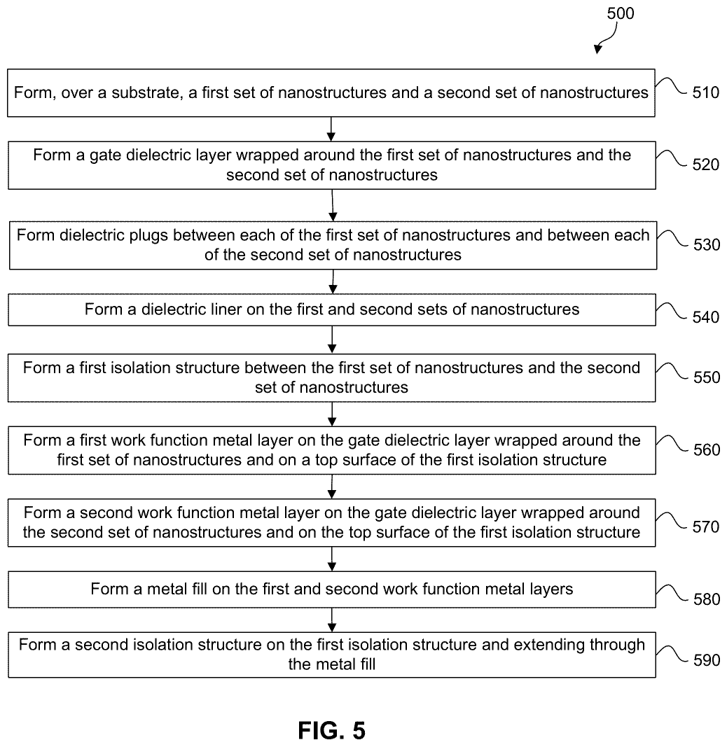

FIG. 5 is a flow diagram of a method 500 for fabricating semiconductor device 100 having a gate isolation wall, in accordance with some embodiments. Method 500 may not be limited to nanostructure transistor devices and can be applicable to other devices that would benefit from the gate isolation wall. Additional fabrication operations may be performed between various operations of method 500 and may be omitted merely for clarity and ease of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently described operations.

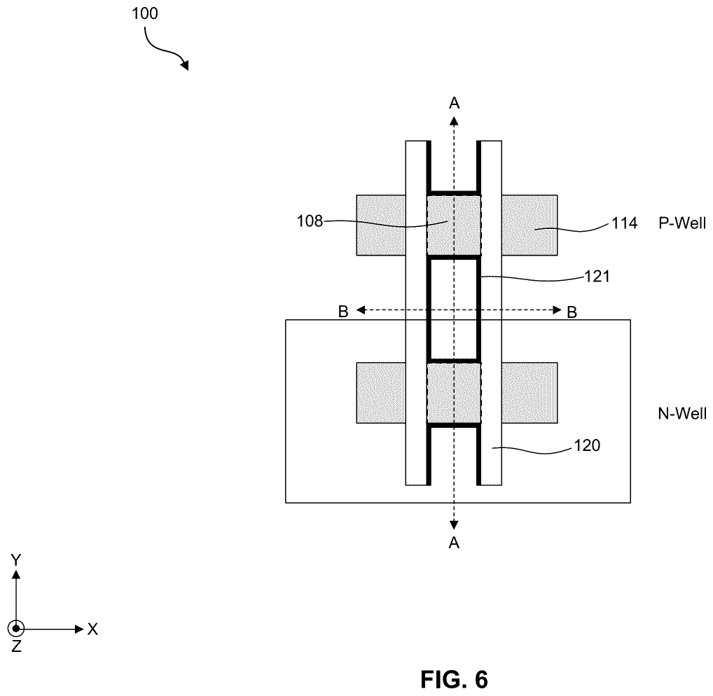

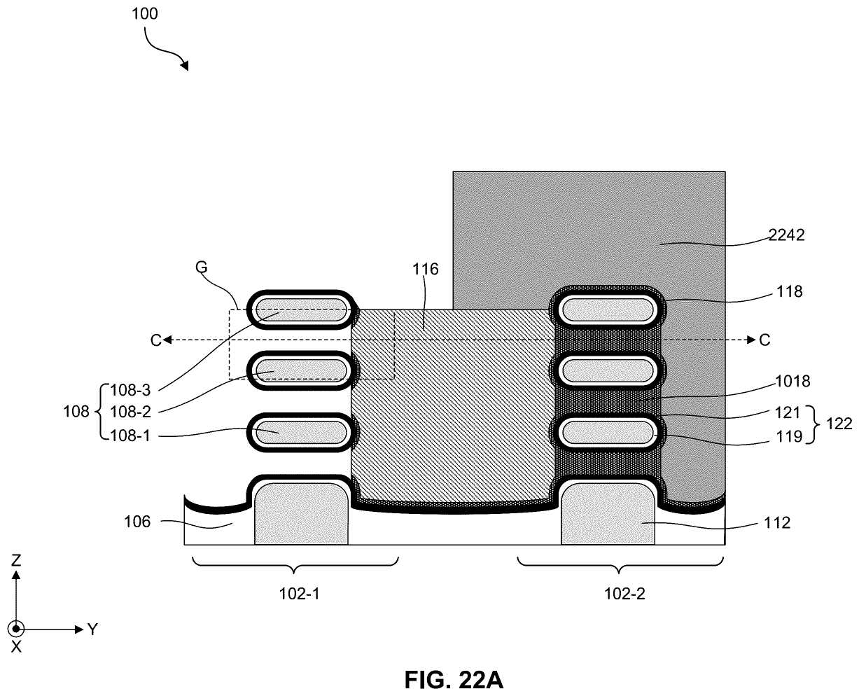

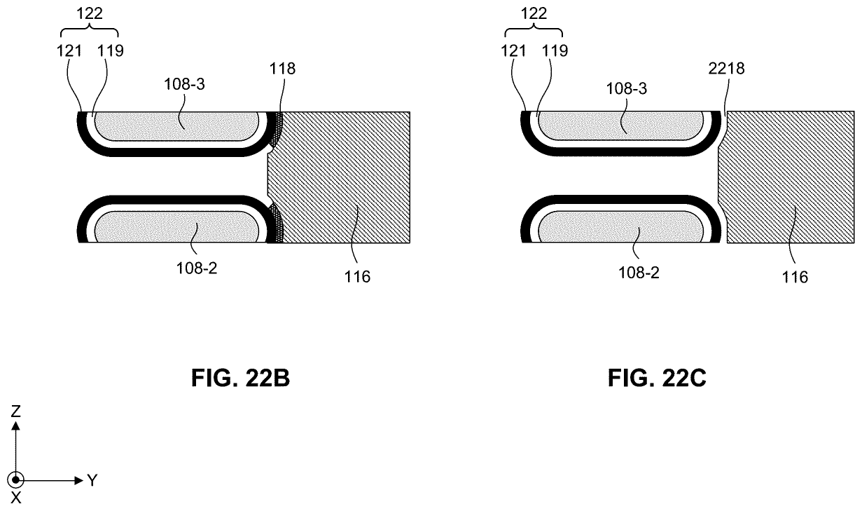

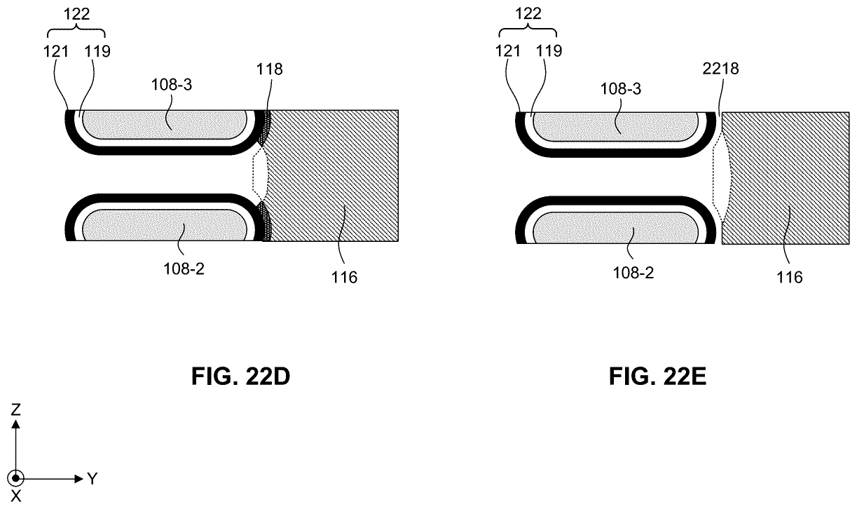

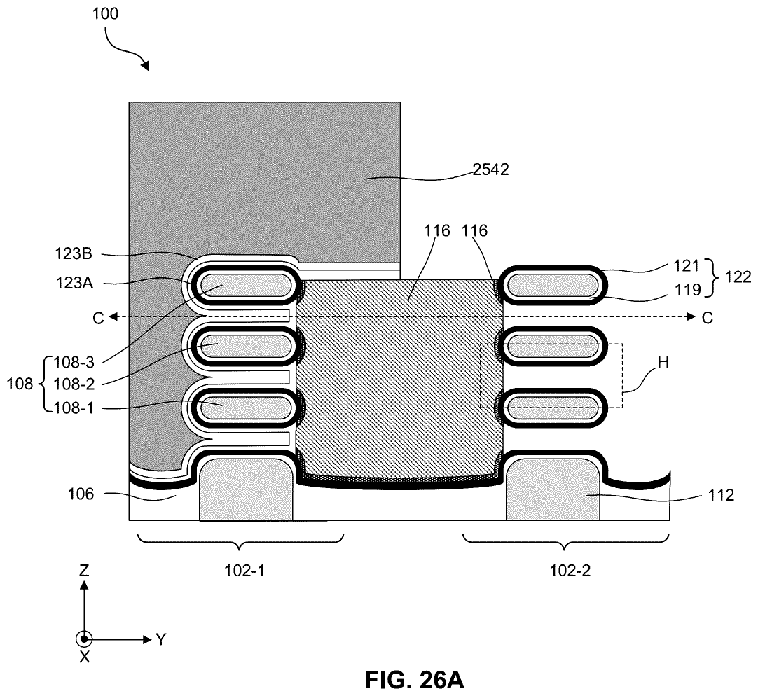

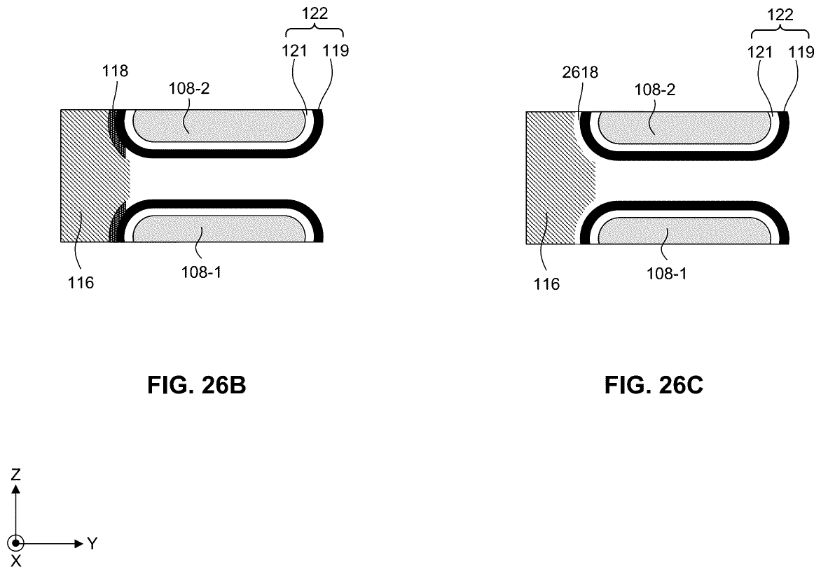

For illustrative purposes, the operations illustrated in FIG. 5 will be described with reference to the example fabrication process for fabricating semiconductor device 100 as illustrated in FIGS. 6-31. FIGS. 6-31 illustrate plane views and cross-sectional views of semiconductor device 100 having the gate isolation wall at various stages of its fabrication, in accordance with some embodiments. In some embodiments, FIGS. 22B-22D illustrate enlarged region G of semiconductor device 100 shown in FIG. 22A. In some embodiments, FIGS. 26B and 26C illustrate enlarged region H of semiconductor device 100 shown in FIG. 26A. Elements in FIGS. 6-31 with the same annotations as elements in FIGS. 1-4 are described above.

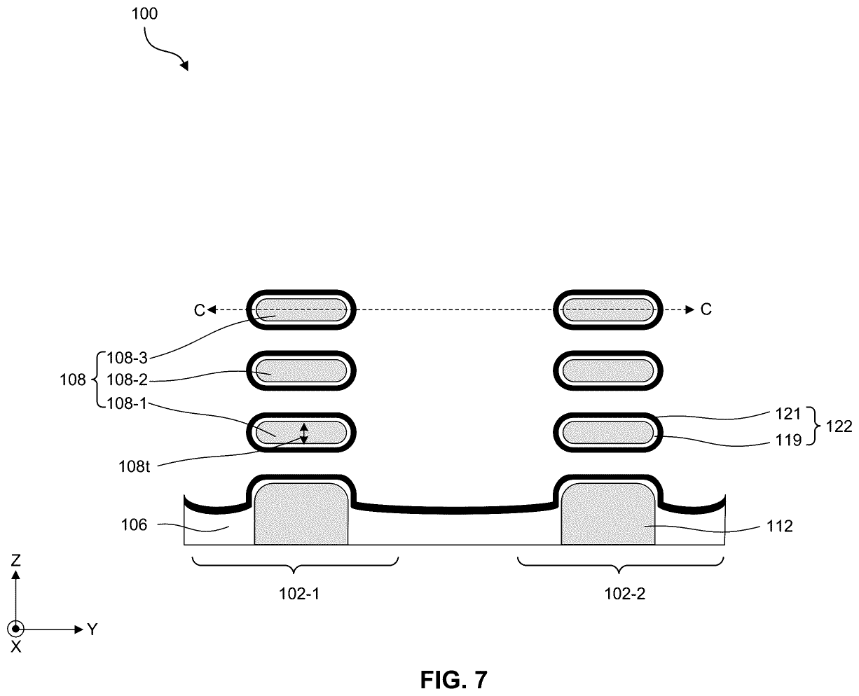

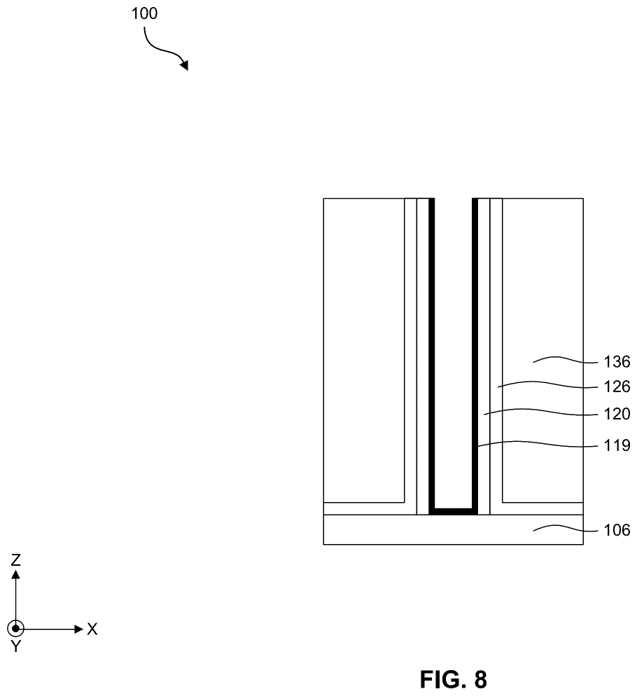

In referring to FIG. 5, method 500 begins with operation 510 and the process of forming, over a substrate, a first set of nanostructures and a second set of nanostructures. For example, as shown in FIGS. 1 and 6-8, first set of nanostructures 108 for nanostructure transistor 102-1 and second set of nanostructures 108 for nanostructure transistor 102-2 can be formed over substrate 104. FIG. 6 illustrates a plane view of semiconductor device 100 across plane C-C shown in FIG. 7, in accordance with some embodiments. FIG. 7 illustrates a cross-sectional view of semiconductor device 100 along line A-A shown in FIG. 6, in accordance with some embodiments. FIG. 8 illustrates a cross-sectional view of semiconductor device 100 along line B-B shown in FIG. 6, in accordance with some embodiments.

In some embodiments, first and second sets of nanostructures 108 can be epitaxially grown on substrate 104 and stacked with additional nanostructures in an alternate configuration. Nanostructures 108 and the additional nanostructures can be patterned by double-or multi-patterning processes described above. The additional nanostructures can be removed in subsequent processes to form nanostructures 108 stacked vertically and separated from each other, as shown in FIG. 7. In some embodiments, each of nanostructures 108 can have a thickness 108t along a Z-axis ranging from about 5 nm to about 15 nm. A space between each of nanostructures 108 along a Z-axis can range from about 9 nm to about 12 nm. In some embodiments, first and second sets of nanostructures 108 can include a semiconductor material different from substrate 104. In some embodiments, first and second sets of nanostructures 108 can include a semiconductor material the same as substrate 104. In some embodiments, substrate 104 and first and second sets of nanostructures 108 can include silicon. In some embodiments, the additional nanostructures can include silicon germanium. In some embodiments, as shown in FIG. 6, nanostructures 108 can be formed in an N-well to build p-type nanostructure transistors. In some embodiments, as shown in FIG. 6, nanostructures 108 can be formed in a P-well to build n-type nanostructure transistors. The N-well and P-well are portions of substrate doped with respective n-type and p-type dopants, upon which nanostructure transistors can be built.

Referring to FIG. 5, in operation 520, a gate dielectric layer is formed wrapping around the first set of nanostructures and the second set of nanostructures. For example, as shown in FIGS. 6-8, gate dielectric layer 122 can be formed wrapping around first and second sets of nanostructures 108. In some embodiments, gate dielectric layer 122 can include interfacial layer 119 formed on nanostructures 108 and high-k dielectric layer 121 formed on interfacial layer 119. In some embodiments, gate dielectric layer 122 can include high-k dielectric layer 121 formed in direct contact with nanostructures 108. In some embodiments, as shown in FIGS. 6-8, high-k dielectric layer 121 can be formed on STI regions 106 and sidewalls of gate spacers 120.

In some embodiments, interfacial layer 119 can include silicon oxide formed by a deposition process or an oxidation process. In some embodiments, high-k dielectric layer 121 can include hafnium oxide, zirconium oxide, and other suitable high-k dielectric materials conformally deposited by atomic layer deposition (ALD), chemical vapor deposition (CVD), or other suitable deposition methods. In some embodiments, interfacial layer 119 can have a thickness ranging from about 1 nm to about 1.5 nm. In some embodiments, high-k dielectric layer 121 can have a thickness ranging from about 1 nm to about 2.5 nm.

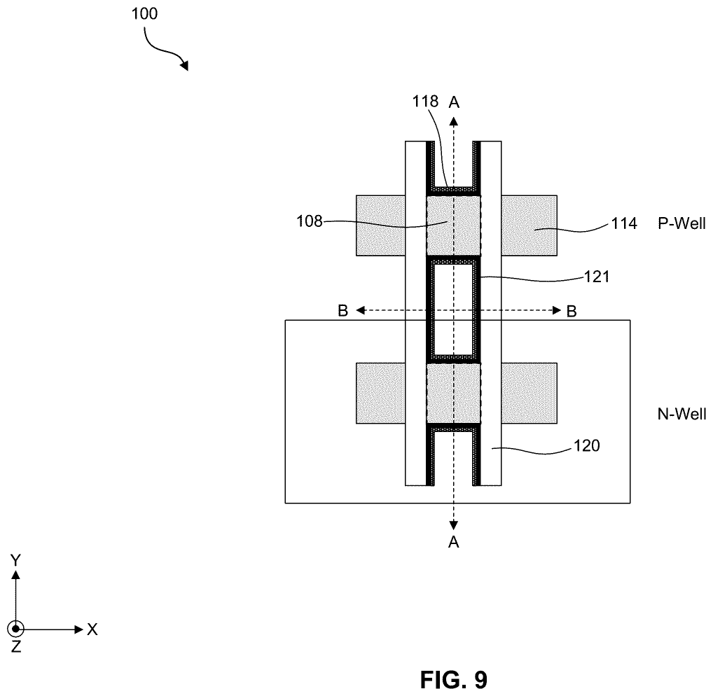

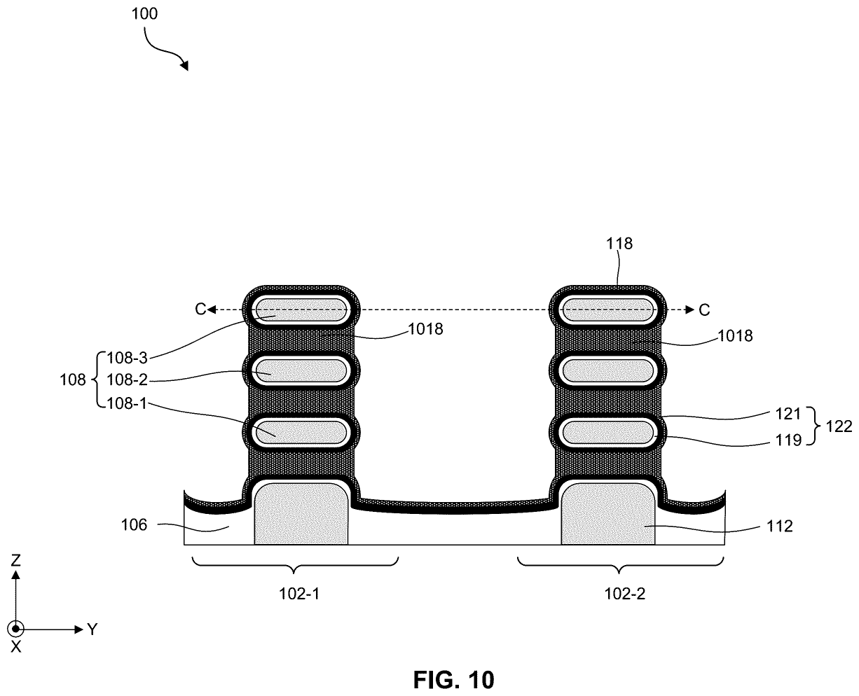

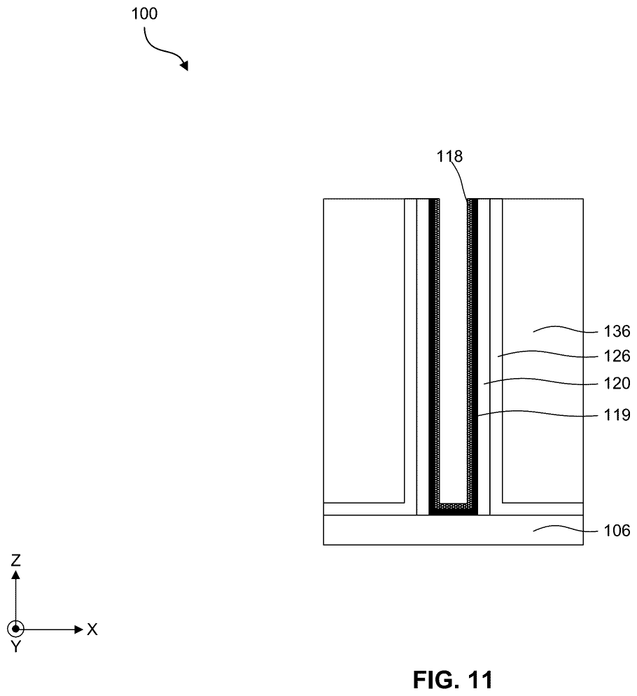

Referring to FIG. 5, in operation 530, dielectric plugs are formed between each of the first set of nanostructures and between each of the second set of nanostructures. For example, as shown in FIGS. 9-11, dielectric plugs 1018 can be formed between each of nanostructures 108. FIG. 9 illustrates a plane view of semiconductor device 100 across plane C-C shown in FIG. 10, in accordance with some embodiments. FIG. 10 illustrates a cross-sectional view of semiconductor device 100 along line A-A shown in FIG. 9, in accordance with some embodiments. FIG. 11 illustrates a cross-sectional view of semiconductor device 100 along line B-B shown in FIG. 9, in accordance with some embodiments.

In some embodiments, the formation of dielectric plugs 1018 can include blanket depositing a dielectric material on high-k dielectric layer 121 and removing the dielectric material outside the space between each of nanostructures 108. In some embodiments, the dielectric material can be blanket deposited by ALD, CVD, or other suitable deposition methods. The dielectric material can fill the space between each of nanostructures 108. In some embodiments, the deposited dielectric material can be etched back to remove the dielectric material outside the space between each of nanostructures 108, for example, the dielectric material on top and sidewall surfaces of nanostructures 108 and the dielectric material between first set of nanostructures 108 in nanostructure transistor 102-1 and second set of nanostructures 108 in nanostructure transistor 102-2. In some embodiments, the deposited dielectric material can be removed by a directional etching process or an anisotropic etching process, such as a plasma dry etching process. In some embodiments, dielectric plugs 1018 can include silicon oxide, aluminum oxide, zirconium oxide, silicon nitride, silicon carbon oxynitride, or other suitable dielectric materials. In some embodiments, dielectric plugs 1018 can have a high etch selectivity (e.g., greater than about 100) with respect to high-k dielectric layer 121. High-k dielectric layer 121 can act as an etch stop layer. After the directional etching process, the dielectric material on side surfaces of nanostructures 108, the top surface of top nanostructures 108-3, and the top surface of STI regions 106 can be removed to expose high-k dielectric layer 121.

Referring to FIG. 5, in operation 540, a dielectric liner is formed on the first and second nanostructures. For example, as shown in FIGS. 9-11, dielectric liner 118 can be formed on high-k dielectric layer 121 wrapping around nanostructures 108 and over STI regions 106. In some embodiments, dielectric liner 118 can be conformally deposited on high-k dielectric layer 121 by ALD, CVD, or other suitable deposition methods. In some embodiments, dielectric liner 118 can have a thickness ranging from about 1 nm to about 3 nm. In some embodiments, dielectric liner 118 can act as the end cap dielectric for nanostructure transistors 102-1 and 102-2. In some embodiments, compared to dielectric plugs 1018, thinner thickness of dielectric liner 118 can improve the control of the end cap dimensions and the uniformity of work function metal layers 123 subsequently formed on nanostructures 108. In some embodiments, dielectric liner 118 can include silicon oxide, aluminum oxide, zirconium oxide, silicon nitride, silicon carbon oxynitride, or other suitable dielectric materials. In some embodiments, dielectric liner 118 and dielectric plugs 1018 can include the same dielectric material and can be removed together in subsequent etching processes. In some embodiments, dielectric liner 118 can include a dielectric material different from dielectric plugs 1018 and dielectric liner 118 and dielectric plugs 1018 can be removed in different etching processes. In some embodiments, dielectric liner 118 can have a high etch selectivity (e.g., greater than about 100) with respect to high-k dielectric layer 121.

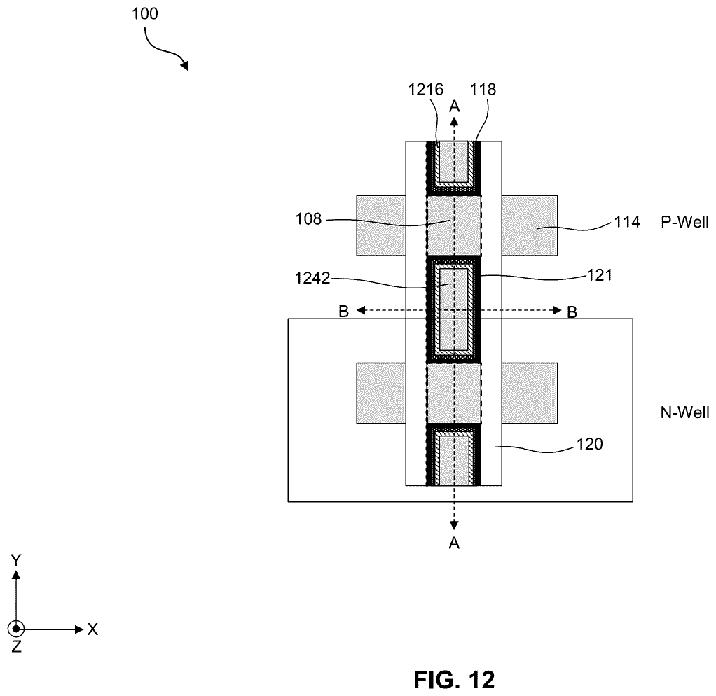

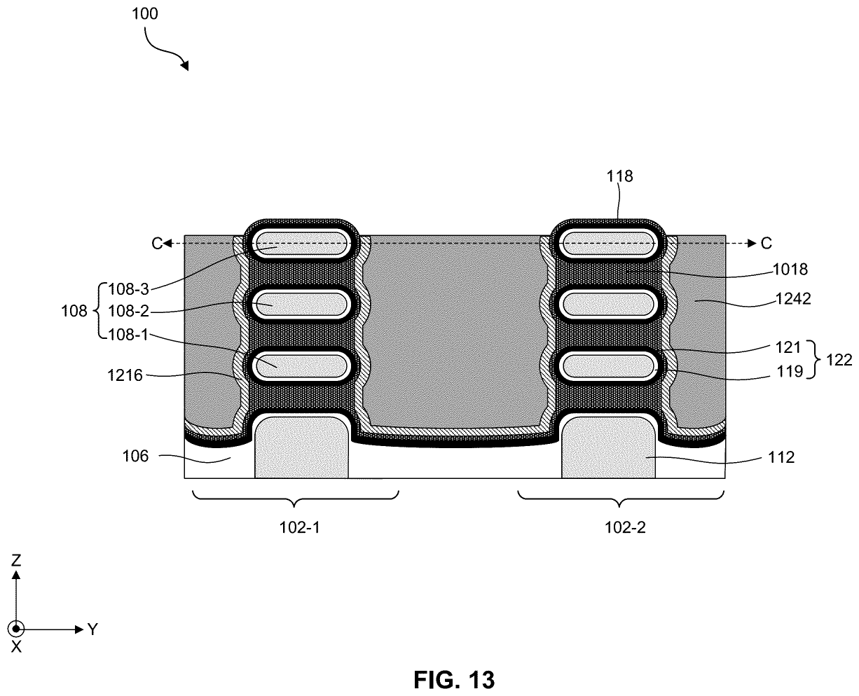

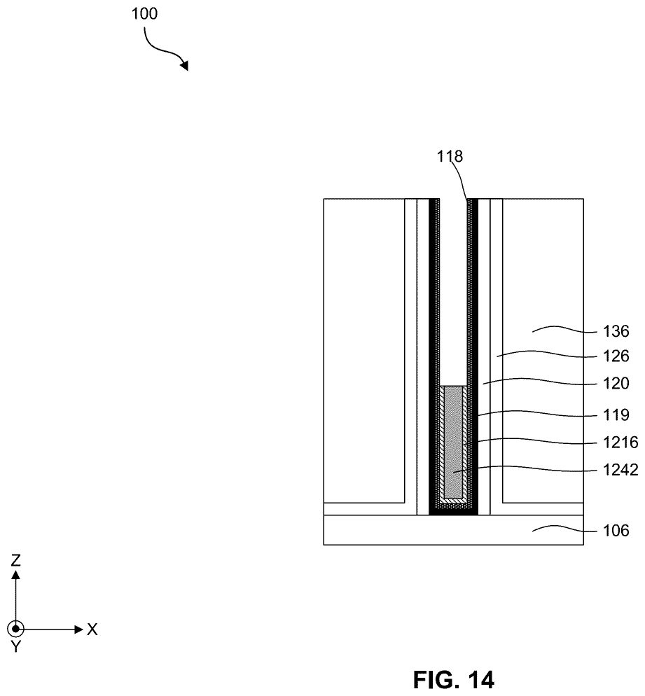

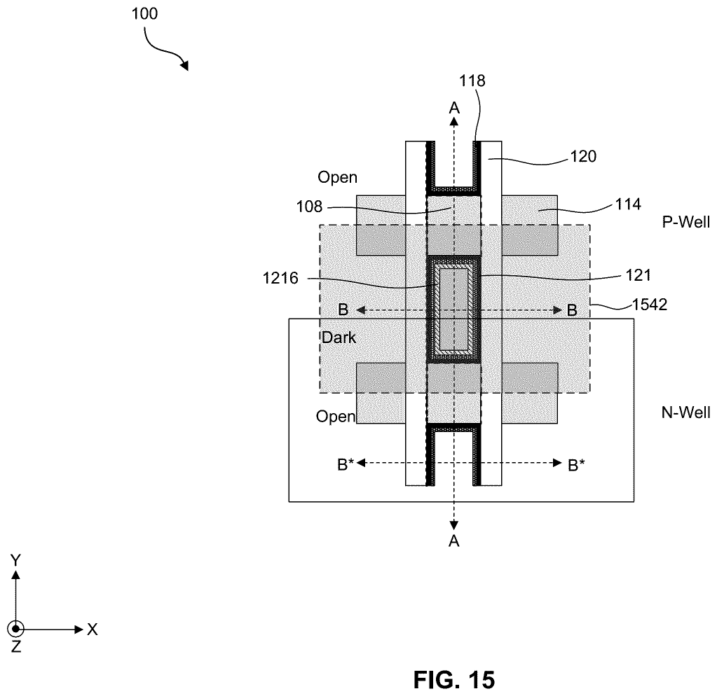

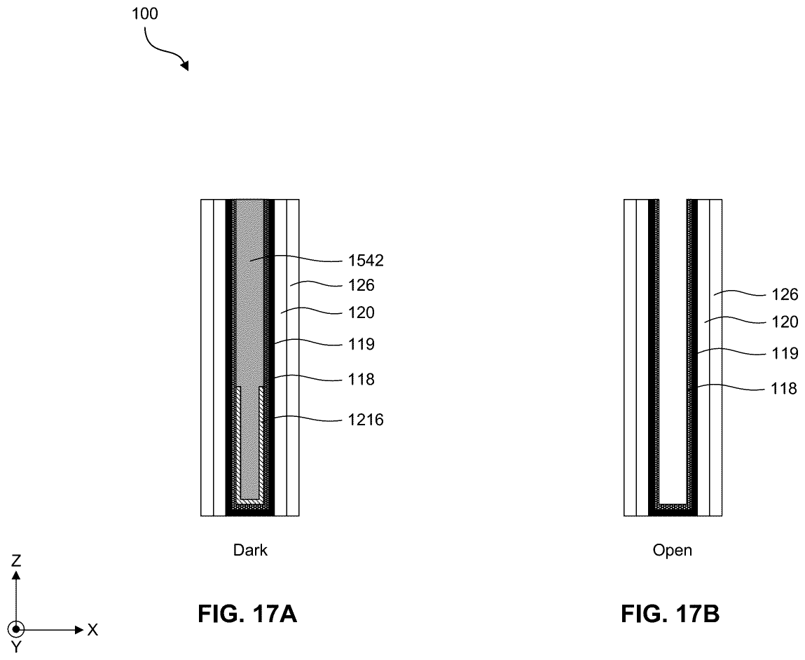

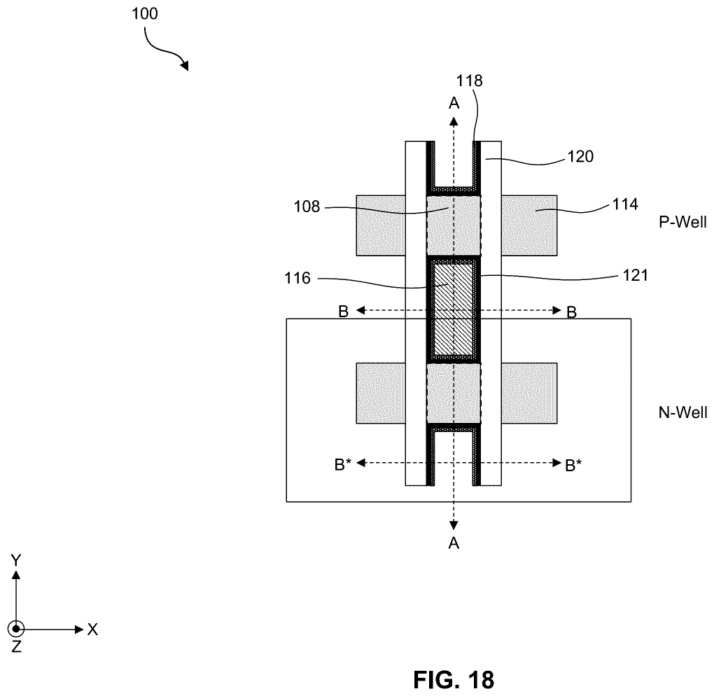

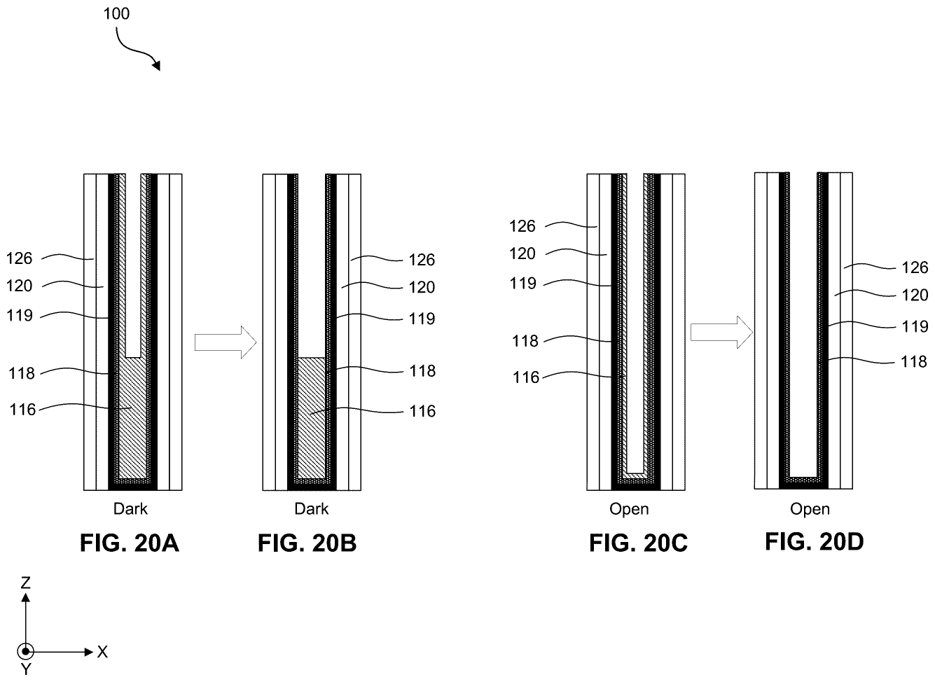

Referring to FIG. 5, in operation 550, a first isolation structure can be formed between the first set of nanostructures and the second set of nanostructures. For example, as shown in FIGS. 12-20D, gate isolation wall 116 can be formed between first set of nanostructures 108 in nanostructure transistor 102-1 and second set of nanostructures 108 in nanostructure transistor 102-2. In some embodiments, the formation of gate isolation wall 116 can include formation of isolation wall liner 1216 and depositing isolation materials on isolation wall liner 1216 between first and second sets of nanostructures 108. FIGS. 12, 15, and 18 illustrate respective plane views of semiconductor device 100 across plane C-C shown in FIGS. 13, 16, and 19, in accordance with some embodiments. FIGS. 13, 16, and 19 illustrate respective cross-sectional views of semiconductor device 100 along line A-A shown in FIGS. 12, 15, and 18, in accordance with some embodiments. FIGS. 14, 17A, and 20A-20B illustrate respective cross-sectional views of semiconductor device 100 along line B-B shown in FIGS. 12, 15, and 18, in accordance with some embodiments. FIGS. 17B and 20C-20D illustrate respective cross-sectional views of semiconductor device 100 along line B*-B* shown in FIGS. 15 and 18, in accordance with some embodiments.

In some embodiments, as shown in FIGS. 12-14, isolation wall liner 1216 can be formed on dielectric liner 118 around nanostructures 108 and over STI regions 106. In some embodiments, isolation wall liner 1216 can be conformally deposited on dielectric liner 118 by ALD, CVD, or other suitable deposition methods. In some embodiments, isolation wall liner 1216 can include a dielectric material, such as silicon oxide, aluminum oxide, zirconium oxide, silicon nitride, and silicon carbon oxynitride.

The formation of isolation wall liner 1216 can be followed by formation of mask layer 1242, as shown in FIGS. 12-14. In some embodiments, mask layer 1242 can be blanket deposited on semiconductor device 100 and can be etched back. A top surface of mask layer 1242 can be at a level between top and bottom surfaces of top nanostructures 108-3. In some embodiments, mask layer 1242 can include a bottom anti-reflection coating and/or other suitable dielectric materials.

The formation of mask layer 1242 can be followed by etching isolation wall liner 1216. In some embodiments, isolation wall liner 1216 on the top surface of top nanostructures 108-3 can be removed by an etching process. Mask layer 1242 can act as an etch stop layer during the etching process. The etching process can align top surfaces of isolation wall liner 1216 and mask layer 1242 at a level between the top and bottom surfaces of top nanostructures 108-3. Accordingly, as shown in FIG. 13, a height of isolation wall liner 1216 on side surfaces of nanostructures 108 can be less than a height of nanostructures 108. In some embodiments, the height of isolation wall liner 1216 can control a coverage of subsequently-formed work function metal layers wrapping around top nanostructures 108-3. The coverage of subsequently-formed work function metal layers on nanostructures 108 can affect the Vt of nanostructure transistors 102-1 and 102-2.

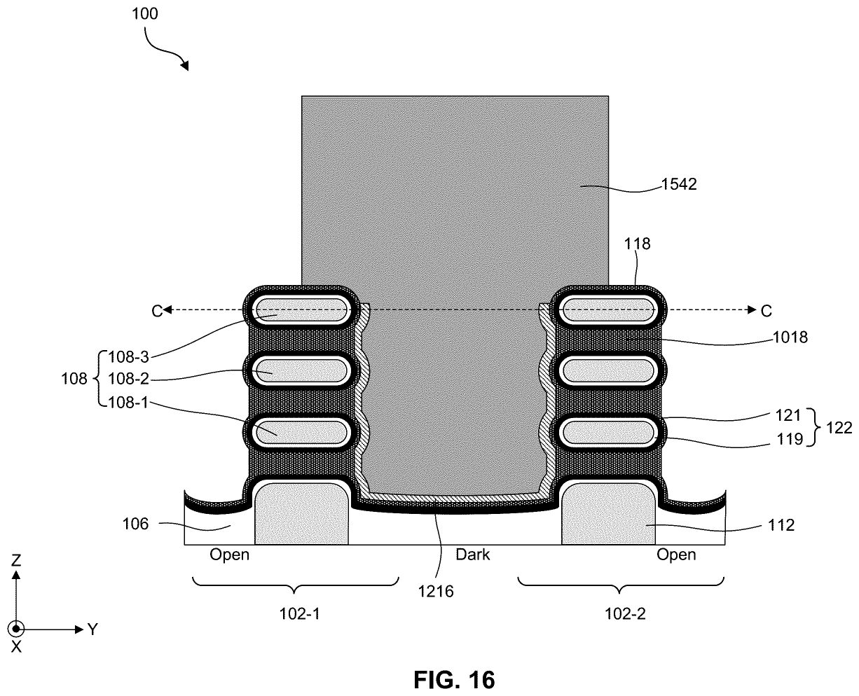

The etching of isolation wall liner 1216 can be followed by removing a portion of isolation wall liner 1216 to define the location of the gate isolation wall, as shown in FIGS. 15-17B. In some embodiments, mask layer 1542 can be formed between first set of nanostructures 108 in nanostructure transistor 102-1 and second set of nanostructures 108 in nanostructure transistor 102-2, as shown in FIGS. 15 and 16. In some embodiments, mask layer 1542 can include a photoresist, a bottom anti-reflection coating, a hard mask, and/or other suitable materials. Mask layer 1542 can cover isolation wall liner 1216 between first and second sets of nanostructures 108. In some embodiments, the regions covered by mask layer 1542 can be referred to as “dark regions,” and the regions not covered by mask layer 1542 can be referred to as “open regions,” as shown in FIGS. 15-17B. Isolation wall liner 1216 not covered by mask layer 1542 can be removed by an etching process, as shown in FIGS. 16 and 17A-17B.

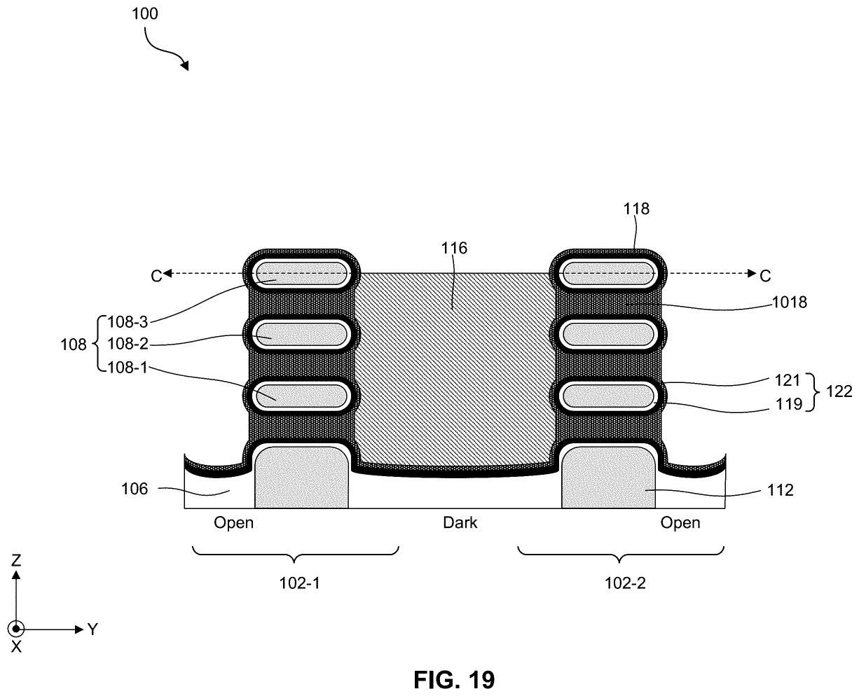

The removal of the portion of isolation wall liner 1216 outside mask layer 1542 can be followed by depositing isolation materials on isolation wall liner 1216 between first and second sets of nanostructures 108, as shown in FIGS. 18-20D. In some embodiments, after removal of mask layer 1542, isolation materials can be blanket deposited on isolation wall liner 1216 and dielectric liner 118 by ALD, CVD, or other suitable deposition methods, as shown in FIGS. 20A and 20C. In some embodiments, the deposited isolation materials can include the same dielectric material as isolation wall liner 1216. Accordingly, the deposited isolation materials between first and second sets of nanostructures 108 can merge with isolation wall liner 1216 and form gate isolation wall 116, as shown in FIG. 19. The isolation materials deposited on dielectric liner 118 can be removed by an etching process. In some embodiments, gate isolation wall 116 and dielectric liner 118 can include different dielectric materials. In some embodiments, the etch selectivity between dielectric liner 118 and gate isolation wall 116 can be greater than about 100 such that the etching process can remove the isolation materials on dielectric liner 118 without removing dielectric liner 118, as shown in FIGS. 20B and 20D. In some embodiments, gate isolation wall 116 and dielectric liner 118 can include the same dielectric material.

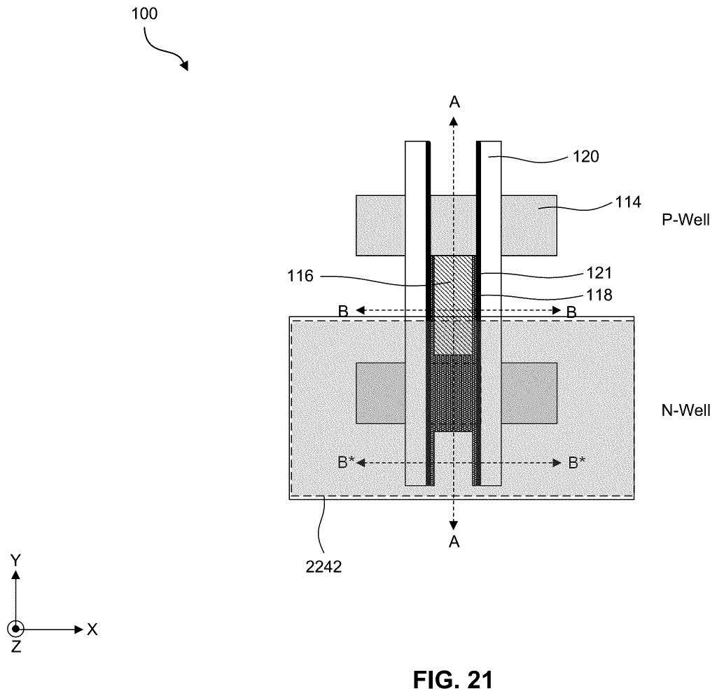

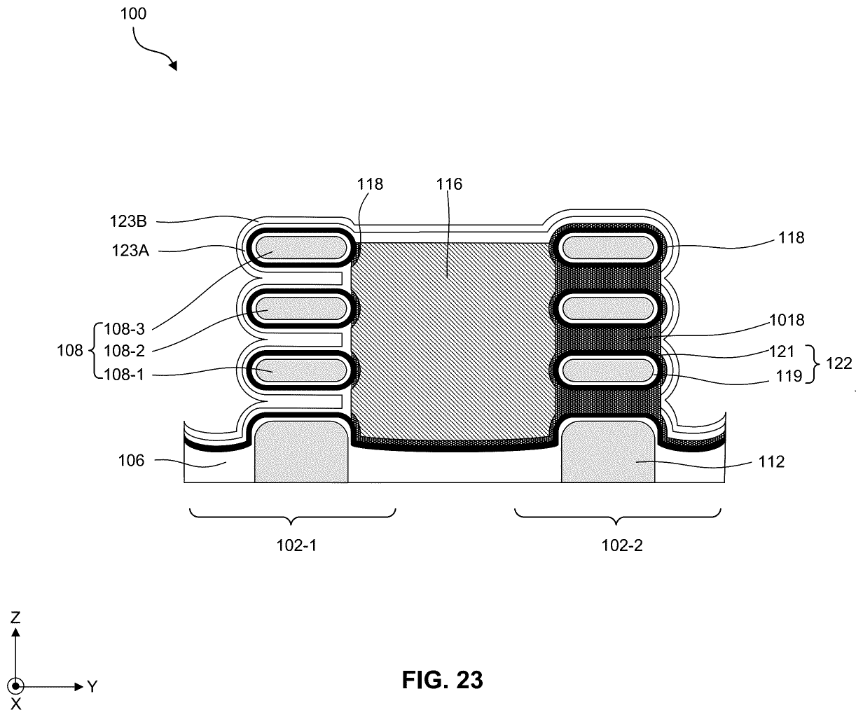

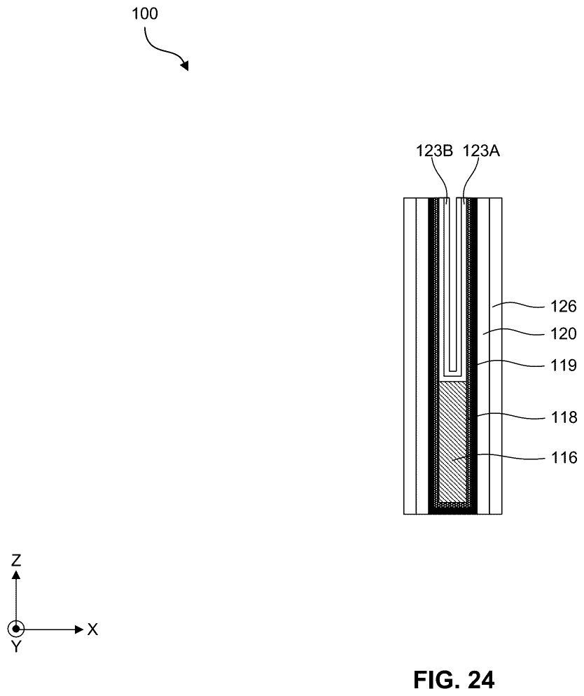

Referring to FIG. 5, in operation 560, a first work function metal layer is formed on the gate dielectric layer wrapped around the first set of nanostructures and on a top surface of the first isolation structure. For example, as shown in FIGS. 21-24, work function metal layers 123A and 123B can be formed on gate dielectric layer 122 wrapped around first set of nanostructures 108 and on the top surface of gate isolation wall 116. FIG. 21 illustrates a plane view of semiconductor device 100 across plane C-C shown in FIG. 22A, in accordance with some embodiments. FIGS. 22A and 23A illustrate cross-sectional views of semiconductor device 100 along line A-A shown in FIG. 21 before and after deposition of work function metal layers, in accordance with some embodiments. FIG. 24 illustrates a cross-sectional view of semiconductor device 100 along line B-B shown in FIG. 21 after deposition of work function metal layers, in accordance with some embodiments. FIGS. 22B and 22C illustrate enlarged region G of semiconductor device 100 having different dielectric materials for dielectric liner 118 and gate isolation wall 116 shown in FIG. 22A, in accordance with some embodiments. In some embodiments, the etch selectivity between dielectric liner 118 and gate isolation wall 116 can be greater than about 100 to control the end cap dimensions. FIGS. 22D and 22E illustrate enlarged region G of semiconductor device 100 having the same dielectric material for dielectric liner 118 and gate isolation wall 116 shown in FIG. 22A, in accordance with some embodiments.

In some embodiments, a mask layer 2242 can be formed on nanostructure transistor 102-2 to cover second set of nanostructures 108. Mask layer 2242 can include a photoresist, a bottom anti-reflection coating, a hard mask, and/or other suitable materials. Dielectric plugs 1018 and dielectric liner 118 around first set of nanostructures 108 can be removed by an etching process. The etching process can expose gate isolation wall 116. After the etching process, as shown in FIGS. 22A-22E, concave surfaces and convex surfaces arranged in an alternate configuration can form on sidewalls of gate isolation wall 116. In some embodiments, as shown in FIG. 22B, a portion of dielectric liner 118 can remain between high-k dielectric layer 121 and gate isolation wall 116 after the etching process. During the removal of the dielectric plugs 1018 and dielectric liner 118, high-k dielectric layer 121 formed on gate spacers 120 can protect gate spacers 120 and prevent gate spacer damage, as shown in FIG. 21. As a result, the metal gate extrusion and S/D epitaxial defects in nanostructure transistor 102-1 can be reduced in subsequent manufacturing processes.

In some embodiments, as shown in FIG. 22C, dielectric liner 118 between high-k dielectric layer 121 and gate isolation wall 116 can be removed after the etching process. As a result, an air gap 2218 can form between high-k dielectric layer 121 and gate isolation wall 116. In some embodiments, air gap 2218 can be filled with work function metals in subsequent processes to improve gate control and mitigate SCEs. In some embodiments, air gap 2218 can be enclosed by work function metal layers 123A and gate isolation wall 116. Air gap 2218 can reduce parasitic capacitance and improve device performance.

In some embodiments, gate isolation wall 116 and dielectric liner 118 can include the same dielectric material and mask layer 2242 can cover second set of nanostructures 108 and gate isolation wall 116. After the etching process, as shown in FIGS. 22D and 22E, extra portions of gate isolation wall 116 indicated by dotted regions in FIGS. 22D and 22E can be removed. Accordingly, additional work function metals can fill between nanostructures 108 of nanostructure transistor 102-1 in subsequent processes, which can further improve gate control and mitigate SCEs.

The removal of dielectric plugs 1018 and dielectric liner 118 around first set of nanostructures 108 can be followed by formation of work function metal layers 123A and 123B, as shown in FIGS. 23 and 24. In some embodiments, mask layer 2242 can be removed and work function metal layers 123A and 123B can be conformally deposited on high-k dielectric layer 121 around first set of nanostructures 108, gate isolation wall 116, and dielectric liner 118. In some embodiments, work function metal layers 123A and 123B can be deposited by ALD, CVD, or other suitable deposition methods. In some embodiments, each of work function metal layers 123A and 123B can have a thickness ranging from about 1 nm to about 3 nm.

In some embodiments, work function metal layers 123A and 123B can include different work function metals to tune Vt of nanostructure transistor 102-1. In some embodiments, work function metal layer 123A can include aluminum, titanium aluminum, titanium aluminum carbon, tantalum aluminum, tantalum aluminum carbon, tantalum silicon carbide, hafnium carbide, or other suitable work function metals. In some embodiments, work function metal layer 123B can include silicon, titanium nitride, titanium silicon nitride, or other suitable work function metals. After deposition of the work function metals, as shown in FIG. 23, work function metal layers 123A and 123B can surround first set of nanostructures 108 and can be in contact with sidewall surfaces of gate isolation wall 116 and dielectric liner 118. In some embodiments, work function metal layer 123A can surround four sides of first set of nanostructures 108, and work function metal layer 123B can surround three sides of first set of nanostructures 108. With dielectric liner 118 and gate isolation wall 116, work function metal layers 123A and 123B can have uniform coverage around nanostructures 108 across different nanostructure transistors and SCEs can be mitigated. Dielectric liner 118 remaining on side surfaces of nanostructures 108 can reduce parasitic capacitance and improve device performance. As shown in FIGS. 23 and 24, work function metal layers 123A and 123B can also be deposited on the top surface of gate isolation wall 116.

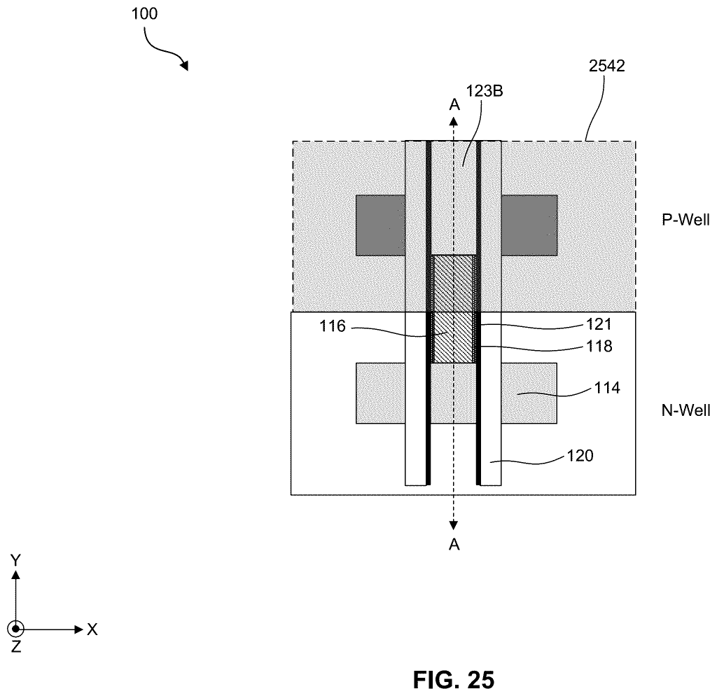

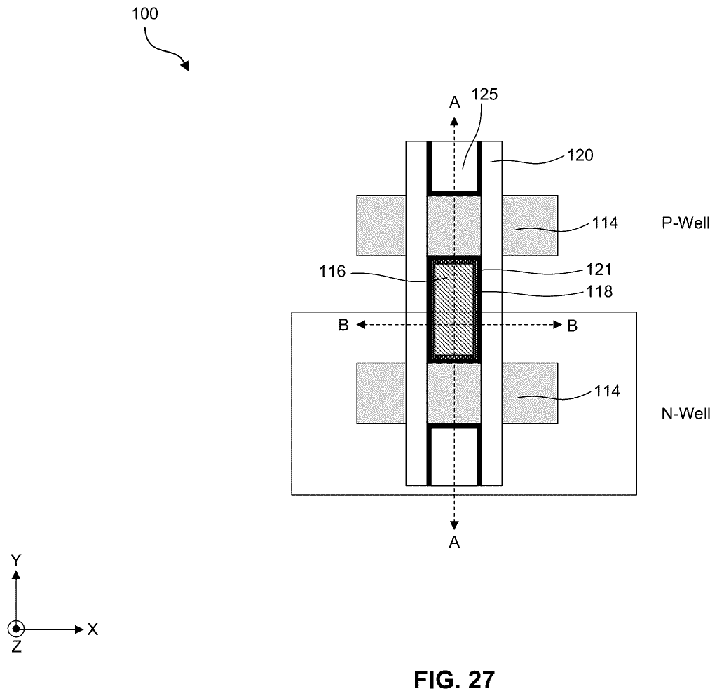

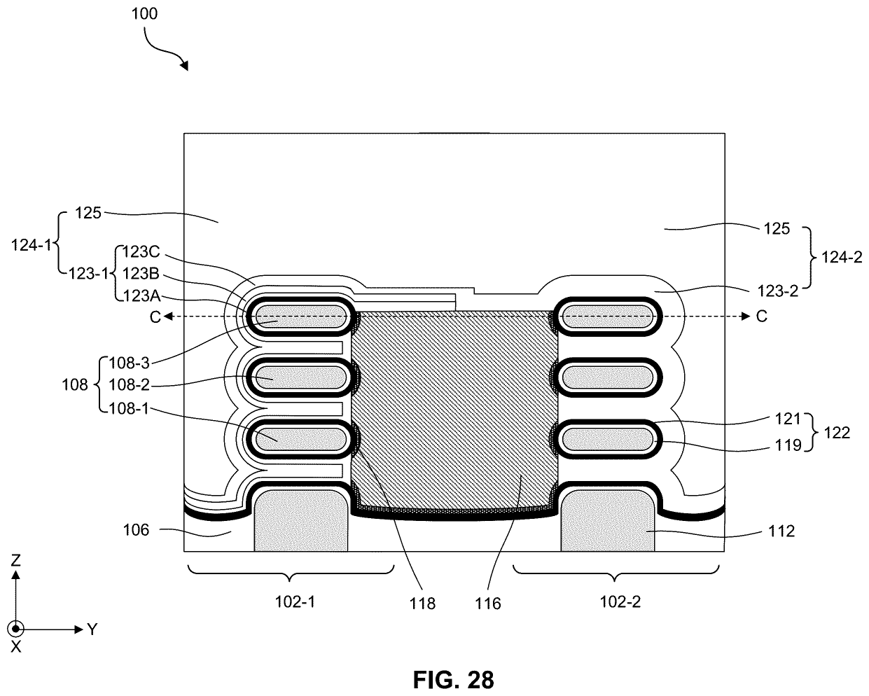

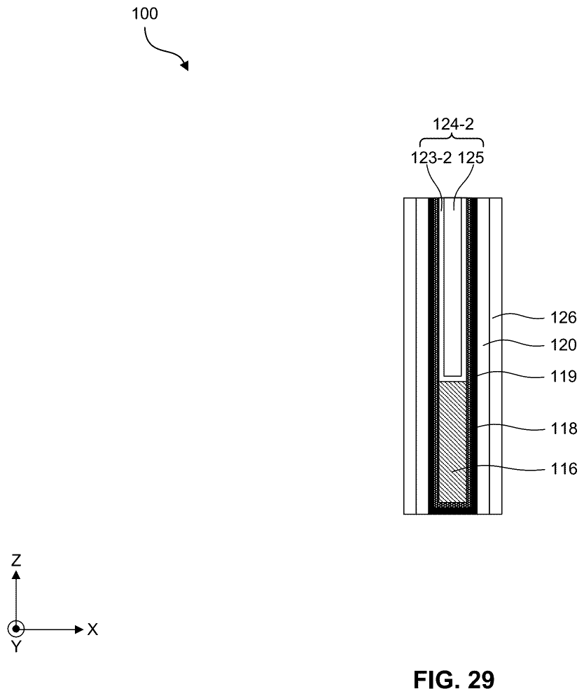

Referring to FIG. 5, in operation 570, a second work function metal layer is formed on the gate dielectric layer wrapped around the second set of nanostructures and on the top surface of the first isolation structure. For example, as shown in FIGS. 25-29, work function metal layer 123C can be formed on gate dielectric layer 122 wrapped around second set of nanostructures 108 and on the top surface of gate isolation wall 116. FIGS. 25 and 27 illustrate respective plane views of semiconductor device 100 across plane C-C shown in FIGS. 26A and 28, in accordance with some embodiments. FIGS. 26A and 28 illustrate respective cross-sectional views of semiconductor device 100 along line A-A shown in FIGS. 25 and 27, in accordance with some embodiments. FIG. 29 illustrates a cross-sectional view of semiconductor device 100 along line B-B shown in FIG. 27, in accordance with some embodiments. FIGS. 26B and 26C illustrate enlarged region H of semiconductor device 100 shown in FIG. 26A, in accordance with some embodiments.

In some embodiments, a mask layer 2542 can be formed on nanostructure transistor 102-1 to cover first set of nanostructures 108. Mask layer 2542 can include a photoresist, a bottom anti-reflection coating, a hard mask, and/or other suitable materials. Dielectric plugs 1018 and dielectric liner 118 around second set of nanostructures 108 can be removed by an etching process. The etching process can expose gate isolation wall 116. After the etching process, as shown in FIGS. 26A-26C, concave surfaces and convex surfaces arranged in an alternate configuration can form on sidewalls of gate isolation wall 116. In some embodiments, as shown in FIG. 26B, a portion of dielectric liner 118 can remain between high-k dielectric layer 121 and gate isolation wall 116 after the etching process. During the removal of the dielectric plugs 1018 and dielectric liner 118, high-k dielectric layer 121 formed on gate spacers 120 can protect gate spacers 120 and prevent gate spacer damage, as shown in FIG. 25. As a result, the metal gate extrusion and S/D epitaxial defects in nanostructure transistor 102-2 can be reduced in subsequent manufacturing processes.

In some embodiments, as shown in FIG. 26C, dielectric liner 118 between high-k dielectric layer 121 and gate isolation wall 116 can be removed after the etching process. As a result, an air gap 2618 can form between high-k dielectric layer 121 and gate isolation wall 116. In some embodiments, air gap 2618 can be filled with work function metals in subsequent processes to improve gate control and mitigate SCEs. In some embodiments, air gap 2618 can be enclosed by subsequently-deposited work function metal layers 123C and gate isolation wall 116. Air gap 2618 can reduce parasitic capacitance and improve device performance. In some embodiments, gate isolation wall 116 and dielectric liner 118 can include the same dielectric material. After the etching process, extra portions of gate isolation wall 116 can be removed (not shown, similar to the dotted regions in FIGS. 22D and 22E). Accordingly, additional work function metals can fill between nanostructures 108 in subsequent processes, which can further improve gate control and mitigate SCEs.

The removal of dielectric plugs 1018 and dielectric liner 118 around second set of nanostructures 108 can be followed by formation of work function metal layer 123C (also referred to as “work function metal layer 123-2”), as shown in FIGS. 27-29. In some embodiments, mask layer 2542 can be removed and work function metal layer 123C can be conformally deposited on high-k dielectric layer 121 around second set of nanostructures 108, gate isolation wall 116, and work function metal layer 123B. In some embodiments, a first portion of work function metal layer 123C deposited around first set of nanostructures 108, together with work function metal layers 123A and 123B, can act as work function metal layer 123-1 for nanostructure transistor 102-1. A second portion of work function metal layer 123C deposited on second set of nanostructures 108 can act as work function metal layer 123-2 for nanostructure transistor 102-2. In some embodiments, work function metal layer 123C can be deposited by ALD, CVD, or other suitable deposition methods. In some embodiments, work function metal layer 123C can have a thickness ranging from about 1 nm to about 6 nm.

In some embodiments, work function metal layer 123C can include titanium nitride, titanium silicon nitride, titanium nitride, tungsten carbon nitride, tungsten, molybdenum, or other suitable work function metals. After deposition of the work function metals, as shown in FIG. 28, work function metal layer 123-2 can surround second set of nanostructures 108 and can be in contact with sidewall surfaces of gate isolation wall 116 and dielectric liner 118. With dielectric liner 118 and gate isolation wall 116, work function metal layer 123-2 can have uniform coverage around nanostructures 108 across different nanostructure transistors and SCEs can be mitigated. Dielectric liner 118 remaining on side surfaces of nanostructures 108 can reduce parasitic capacitance and improve device performance. As shown in FIGS. 28 and 29, work function metal layer 123-2 can also be deposited on the top surface of gate isolation wall 116.

Referring to FIG. 5, in operation 580, a metal fill is formed on the first and second work function metal layers. For example, as shown in FIGS. 27-29, metal fill 125 can be formed on work function metal layers 123-1 and 123-2. In some embodiments, metal fill 125 can be deposited over first set of nanostructures 108, gate isolation wall 116, second set of nanostructures 108, and STI regions 106. In some embodiments, metal fill 125 can be blanket deposited by ALD, CVD, or other deposition methods. In some embodiments, metal fill 125 can include titanium, tantalum, aluminum, cobalt, tungsten, nickel, ruthenium, or other suitable conductive materials. In some embodiments, as shown in FIG. 28, metal fill 125 and work function metal layers 123-1 can act as gate structure 124-1 for nanostructure transistor 102-1. Metal fill 125 and work function metal layer 123-2 can act as gate structure 124-2 for nanostructure transistor 102-1.

Referring to FIG. 5, in operation 590, a second isolation structure is formed on the first isolation structure and extending through the metal fill. For example, as shown in FIGS. 1-4, gate isolation structure 130 can be formed on gate isolation wall 116 and extending through metal fill 125. In some embodiments, an opening can be formed in metal fill 125 between nanostructure transistors 102-1 and 102-2 by a patterning process and an etching process. The opening can extend through metal fill 125 to isolate gate structures 124-1 and 124-2. A dielectric material can be blanket deposited to fill the opening and form gate isolation structure 130. In some embodiments, the opening can extend vertically through gate isolation wall 116 and into STI regions 106. Accordingly, gate isolation structure 130 can be in contact with STI regions 106. In some embodiments, gate isolation structure 130 can be confined within gate spacers 120 as shown in FIGS. 1 and 2A. In some embodiments, as shown by dashed region F in FIG. 4, gate isolation structure 130 can extend horizontally along an X-axis across gate spacers 120 and ESL 126 into ILD layer 136. In some embodiments, the deposition of the dielectric material can be followed by a chemical mechanical polishing (CMP) process to planarize top surfaces of gate isolation structure 130, gate structures 124, gate spacers 120, and ILD layer 136, as shown in FIG. 1.

In some embodiments, as shown in FIGS. 2A and 3A, a width of gate isolation structure 130 is less than a width of gate isolation wall 116. In some embodiments, a ratio of the width of gate isolation structure 130 to the width of gate isolation wall 116 can range from about % to about 80%. If the ratio is less than about 30%, gate isolation structure 130 may not isolate gate structures 124-1 and 124-2. If the ratio is greater than about 80%, the coverage of work function metal layers 123 around nanostructures 108 may become nonuniform and the Vt uniformity across nanostructure transistors in semiconductor device 100 may degrade.

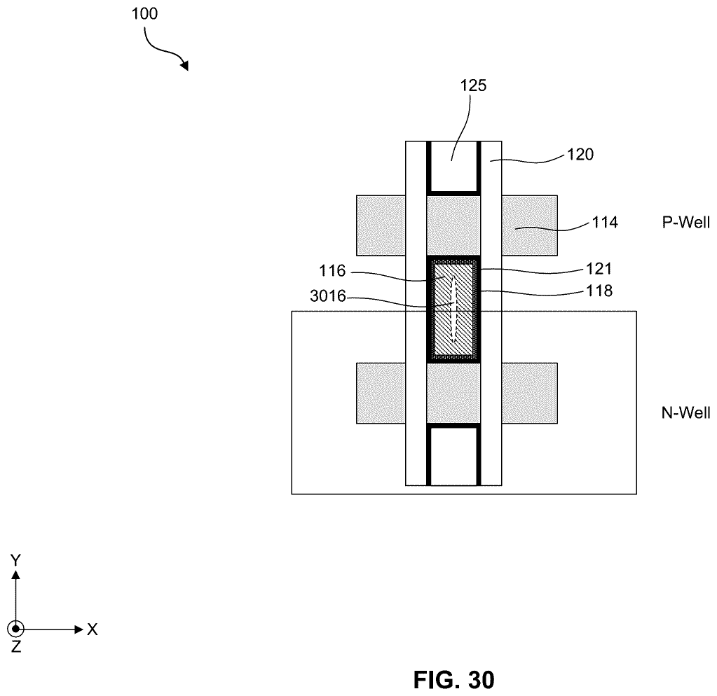

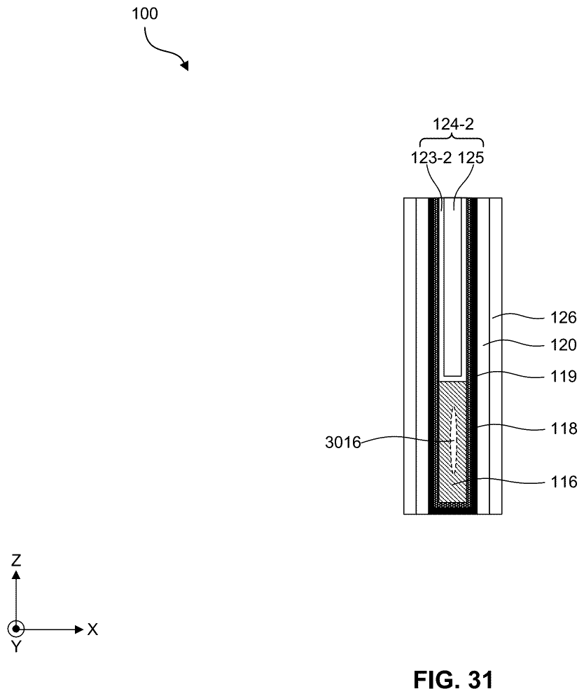

In some embodiments, as shown in FIGS. 30 and 31, a seam 3016 can form in gate isolation wall 116 during deposition. As shown in FIGS. 30 and 31, seam 3016 can be confined by high-k dielectric layer 121 and gate spacers 120. Though work function metals and/or metal fills can fill in seam 3016, gate structures 124 may not be shorted to adjacent S/D contact structures, such as S/D contact structures 132 in FIG. 1, due to the confinement of high-k dielectric layer 121 and gate spacers 120. Accordingly, gate isolation wall 116 can reduce the electrical short defects between the metal gate structures and the S/D contact structures.

Various embodiments in the present disclosure provide example methods for forming gate isolation wall 116 in semiconductor device 100 having nanostructure transistors 102-1 and 102-2. Each of nanostructure transistors 102-1 and 102-2 can have nanostructures 108 and gate dielectric layer 122 wrapped around nanostructures 108. Nanostructure transistor 102-1 can include work function metal layers 123-1 around nanostructures 108. Nanostructure transistor 102-2 can include work function metal layer 123-2 around nanostructures 108. Gate isolation wall 116 can be disposed between nanostructure transistors 102-1 and 102-2 and in contact with work function metal layers 123-1 and 123-2. Gate isolation structure 130 can be disposed on gate isolation wall 116 to electrically isolate gate structures 124-1 and 124-2. In some embodiments, nanostructure transistors 102-1 and 102-2 can include dielectric liner 118 between nanostructures 108 and gate isolation wall 116. In some embodiments, nanostructure transistors 102-1 and 102-2 can include air gap 318 between nanostructures 108 and gate isolation wall 116. With gate isolation wall 116 and dielectric liner 118, the Vt uniformity across nanostructure transistors in semiconductor device 100 can be improved, the metal gate extrusion defects and S/D epitaxial defects can be reduced, and the electrical short defects between gate structures 124 and the S/D contact structures can be reduced.

In some embodiments, a semiconductor structure includes a set of nanostructures on a substrate, a gate dielectric layer wrapped around the set of nanostructures, a work function metal layer on the gate dielectric layer and around the set of nanostructures, and an isolation structure adjacent to the set of nanostructures and in contact with the work function metal layer. A portion of the work function metal layer is on a top surface of the isolation structure.

In some embodiments, a semiconductor device includes first and second sets of nanostructures on a substrate, a gate dielectric layer wrapped around the first and second sets of nanostructures, a first work function metal layer on the gate dielectric layer and around the first set of nanostructures, a second work function metal layer on the gate dielectric layer and around the second set of nanostructures, a first isolation structure between the first and second sets of nanostructures and in contact with the first and second work function metal layers, and a second isolation structure on the first isolation structure. The gate dielectric layer is on sidewall surfaces of the first isolation structure. A first width of the first isolation structure is greater than a second width of the second isolation structure.

In some embodiments, a method includes forming a first set of nanostructures and a second set of nanostructures over a substrate, forming a gate dielectric layer wrapped around the first set of nanostructures and the second set of nanostructures, forming dielectric plugs between each of the first set of nanostructures and between each of the second set of nanostructures, forming a dielectric liner on the first and second sets of nanostructures, and forming a first isolation structure between the first set of nanostructures and the second set of nanostructures. The method further includes removing the dielectric plugs between each of the first set of nanostructures and between each of the second set of nanostructures, forming a first work function metal layer on the gate dielectric layer wrapped around the first set of nanostructures and on a top surface of the first isolation structure, and forming a second work function metal layer on the gate dielectric layer wrapped around the second set of nanostructures and on the top surface of the first isolation structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a set of nanostructures on a substrate;
a gate dielectric layer wrapped around the set of nanostructures;
a work function metal layer on the gate dielectric layer and around the set of nanostructures; and
an isolation structure adjacent to the set of nanostructures and in contact with the work function metal layer, wherein a portion of the work function metal layer is on a top surface of the isolation structure.

2. The semiconductor structure of claim 1, wherein the isolation structure has a sidewall adjacent to the work function metal layer, and wherein the sidewall includes concave and convex surfaces arranged in an alternate configuration.

3. The semiconductor structure of claim 1, further comprising an air gap between the gate dielectric layer and the isolation structure.

4. The semiconductor structure of claim 1, further comprising a dielectric liner between the gate dielectric layer and the isolation structure.

5. The semiconductor structure of claim 1, wherein an additional portion of the work function metal layer is between the gate dielectric layer and the isolation structure.

6. The semiconductor structure of claim 1, wherein a height of the isolation structure is less than a height of the set of nanostructures.

7. The semiconductor structure of claim 1, wherein the gate dielectric layer comprises a high-k dielectric layer between the isolation structure and the set of nanostructures.

8. The semiconductor structure of claim 1, wherein the work function metal layer comprises a first work function metal sublayer surrounding four sides of the set of nanostructures and a second work function metal sublayer surrounding three sides of the set of nanostructures.

9. A semiconductor structure, comprising:
first and second sets of nanostructures on a substrate;
a gate dielectric layer wrapped around the first and second sets of nanostructures;
a first work function metal layer on the gate dielectric layer and around the first set of nanostructures;
a second work function metal layer on the gate dielectric layer and around the second set of nanostructures;
a first isolation structure between the first and second sets of nanostructures and in contact with the first and second work function metal layers, wherein the gate dielectric layer is on sidewall surfaces of the first isolation structure; and
a second isolation structure on the first isolation structure, wherein a width of the first isolation structure is greater than a width of the second isolation structure.

10. The semiconductor structure of claim 9, further comprising:
a first air gap between the first set of nanostructures and the first isolation structure; and
a second air gap between the second set of nanostructures and the first isolation structure.

11. The semiconductor structure of claim 9, further comprising a dielectric liner between the gate dielectric layer and the first isolation structure.

12. The semiconductor structure of claim 9, further comprising:
a metal fill on the first isolation structure and the first and second work function metal layers, wherein the second isolation structure extends through the metal fill and is in contact with a top surface of the first isolation structure.

13. The semiconductor structure of claim 9, further comprising:
a metal fill on the first isolation structure and the first and second work function metal layers, wherein the second isolation structure extends through the metal fill and the first isolation structure.

14. A method, comprising:
forming, over a substrate, a first set of nanostructures and a second set of nanostructures;
forming a gate dielectric layer wrapped around the first set of nanostructures and the second set of nanostructures;
forming dielectric plugs between each of the first set of nanostructures and between each of the second set of nanostructures;
forming a dielectric liner on the first and second sets of nanostructures;
forming a first isolation structure between the first set of nanostructures and the second set of nanostructures;
removing the dielectric plugs between each of the first set of nanostructures and between each of the second set of nanostructures;
forming a first work function metal layer on the gate dielectric layer wrapped around the first set of nanostructures and on a top surface of the first isolation structure; and
forming a second work function metal layer on the gate dielectric layer wrapped around the second set of nanostructures and on the top surface of the first isolation structure.

15. The method of claim 14, further comprising:
forming a metal fill on the first and second work function metal layers, wherein the metal fill is above the first isolation structure.

16. The method of claim 15, further comprising forming a second isolation structure on the first isolation structure, wherein the second isolation structure extends through the metal fill and is in contact with the first isolation structure.

17. The method of claim 16, wherein forming the second isolation structure comprises:
etching the metal fill to form an opening above the first isolation structure; and
filling the opening with a dielectric material.

18. The method of claim 16, wherein forming the second isolation structure comprises:
etching the metal fill and the first isolation structure to form an opening; and
filling the opening with a dielectric material.

19. The method of claim 14, further comprising:
removing the dielectric liner on each of the first set of nanostructures and on each of the second set of nanostructures, wherein a portion of the dielectric liner remains between the first isolation structure and the first set of nanostructures and between the first isolation structure and the second set of nanostructures.

20. The method of claim 14, further comprising:
removing the dielectric liner from the first and second sets of nanostructures, wherein an air gap forms between the first isolation structure and the first set of nanostructures and between the first isolation structure and the second set of nanostructures.
